(19) United States
(12) Patent Application Publication
(10) Pub. No.: US 2026/0101600 A1
(43) Pub. Date: Apr. 9, 2026

(54) EMBEDDED CONTACT FOR SPAD APPLICATIONS

(71) Applicant: SEMICONDUCTOR COMPONENTS INDUSTRIES, LLC, Scottsdale, AZ (US)

(72) Inventors: Swarnal BORTHAKUR, Boise, ID (US); Marc Allen SULFRIDGE, Boise, ID (US); Bartosz Piotr BANACHOWICZ, San Jose, CA (US)

(73) Assignee: SEMICONDUCTOR COMPONENTS INDUSTRIES, LLC, Scottsdale, AZ (US)

(21) Appl. No.: 18/905,789

(22) Filed: Oct. 3, 2024

(51) Int. Cl. H01L 27/146

(52) U.S. Cl. CPC H10F 39/807; H10F 39/011; H10F 39/811; H10F 39/18

(57) ABSTRACT

Systems, devices, and methods are described for locating a contact for single-photon avalanche diode (SPAD) in an isolation trench structure of a SPAD-based imager. Systems, devices, and methods may include a frontside isolation trench structure disposed between neighboring SPAD pixels, where the trench is lined with a continuous passivation layer having an opening that allows a conductive material filling the trench to contact the substrate and form a buried contact for one or more neighboring SPADs. The trench may include a stepped trench having the opening in the passivation layer proximate to the stepped region. The trench may include the opening in the passivation layer toward the bottom of the frontside trench. The trench may include a backside trench having a hi-k material. The backside trench may be continuous, or segmented and/or overlapping. Buried SPAD contacts as described herein may allow for reduced pixel size.

### BACKGROUND

This application relates generally to single-photon avalanche diode (SPAD) based devices and, more particularly, to imagers that use an array of SPAD pixels for detecting photons.

Image sensors (also referred to as imagers) may be formed from a two-dimensional array of photo-sensing pixels. Each pixel typically includes a photosensitive element that receives incident photons and converts the photons into electrical signals. The photosensitive element may be a photodiode.

SPAD-based imagers may use SPADs configured to detect single photons. A photon incident on a SPAD device may initiate an avalanche current that can be detected by appropriate circuitry of the SPAD-based imager. A SPAD pixel may generate photons during avalanche, which may travel to neighboring SPAD pixels and cause one or more of them to avalanche. These additional avalanche currents are the result of crosstalk and are not desirable. Isolation structures may be placed between SPAD pixels to prevent crosstalk and/or other undesirable behavior.

SPAD pixels continue to shrink, forcing the cathode and anode of the SPAD device closer together. SPAD devices operate under a large reverse bias voltage between their cathodes and anodes. For small pixels, the electric field between the anode and cathode becomes large and causes unwanted edge breakdown of the avalanche region of the SPAD.

It would therefore be desirable to provide improved devices and methods for forming SPAD pixels.

### BRIEF DESCRIPTION OF DRAWING FIGURES

FIG. 1 is a circuit diagram showing an exemplary SPAD device, in accordance with an embodiment.

FIG. 2 is a cross-sectional side view of an illustrative backside-illuminated (BSI) SPAD-based semiconductor device.

FIGS. 3A-E are cross-sectional views at various stages of fabrication of an illustrative SPAD-based semiconductor device with an isolation trench structure having a conductive material located between annular trenches and electrically coupled with the substrate at the bottom of the trench structure, in accordance with an embodiment.

FIGS. 4A-E are cross-sectional views at various stages of fabrication of an illustrative SPAD-based semiconductor device with an isolation trench structure having a frontside trench and a backside trench, in accordance with an embodiment.

FIG. 5A is a top view of an illustrative SPAD-based semiconductor device showing the relative horizontal arrangement of the components of an isolation trench structure having a frontside trench and a segmented backside trench, in accordance with an embodiment.

FIGS. 5B-C are cross-sectional views at various locations in the SPAD-based semiconductor device of FIG. 5A, in accordance with an embodiment.

FIGS. 6A-E are cross-sectional views at various stages of fabrication of an illustrative SPAD-based semiconductor device having a first stepped isolation trench structure that includes a conductive material contacting the substrate through an opening in a passivation layer at the stepped region, in accordance with an embodiment.

FIGS. 7A-E are cross-sectional views at various stages of fabrication of an illustrative SPAD-based semiconductor device having a second stepped isolation trench structure that includes a conductive material contacting the substrate through an opening in a passivation layer at the stepped region, in accordance with an embodiment.

FIGS. 8A-E are cross-sectional views at various stages of fabrication of an illustrative SPAD-based semiconductor device having a third stepped isolation trench structure that includes a conductive material contacting the substrate through an opening in a passivation layer at the stepped region, in accordance with an embodiment.

FIGS. 9A-E are cross-sectional views at various stages of fabrication of an illustrative SPAD-based semiconductor device having a fourth stepped isolation trench structure that includes a conductive material contacting the substrate through an opening in a passivation layer at the stepped region, in accordance with an embodiment.

FIG. 10A is a top view showing the relative horizontal arrangement of the components of an illustrative SPAD-based semiconductor device having the third stepped isolation trench structure located substantially at the corners of SPAD pixels, in accordance with an embodiment.

FIGS. 10B-D are cross-sectional views at various locations in the SPAD-based semiconductor device of FIG. 10A, in accordance with an embodiment.

FIG. 11A is a top view showing the relative horizontal arrangement of the components of an illustrative SPAD-based semiconductor device with an isolation trench structure having a frontside trench and a segmented backside trench and a contact with the substrate substantially in the corners of the SPAD pixels, in accordance with an embodiment.

FIGS. 11B-C are cross-sectional views at various locations in the SPAD-based semiconductor device of FIG. 11A, in accordance with an embodiment.

FIG. 12A is a top view showing the relative horizontal arrangement of the components of an illustrative SPAD-based semiconductor device with another isolation trench structure having a frontside trench and a segmented backside trench and a contact with the substrate substantially in the corners of the SPAD pixels, in accordance with an embodiment.

FIGS. 12B-C are cross-sectional views at various location in the SPAD-based semiconductor device of FIG. 12A, in accordance with an embodiment.

FIGS. 13A-D are cross-sectional views at various stages of fabrication of an illustrative SPAD-based semiconductor device having an isolation trench structure that includes a conductive material contacting the substrate through an opening in a passivation layer proximate to the frontside of the substrate, in accordance with an embodiment.

FIGS. 14A-D are cross-sectional views at various stages of fabrication of an illustrative SPAD-based semiconductor device having an isolation trench structure partially filled with a passivation layer and including a conductive material contacting the substrate proximate to the frontside of the substrate, in accordance with an embodiment.

FIGS. 15A-E are cross-sectional views at various stages of fabrication of an illustrative SPAD-based semiconductor device having an isolation trench structure filled with a first conductive material and having a second conductive material contacting the substrate at an opening in a passivation layer proximate to the frontside of the substrate, in accordance with an embodiment.

FIGS. 16A-D illustrate exemplary geometrical arrangements of representative isolation trench structures, in accordance with an embodiment.

### BRIEF SUMMARY

Various embodiments relate to systems, devices, and methods for trench isolation structures having a buried contact for one or more SPAD pixels.

In various embodiments, a semiconductor device may include a substrate having a frontside and a backside, a first single-photon avalanche diode (SPAD) in the substrate and having a first contact proximate to the frontside of the substrate, wherein the first contact is one of either a cathode or an anode of the SPAD, a second SPAD in the substrate and located next to the first SPAD, and a trench isolation structure in the substrate interposed between the first and second SPAD, comprising: a frontside trench, a continuous passivation layer lining the frontside trench, wherein the passivation layer includes an opening at a horizontal surface of the frontside trench, and a conductive material disposed within the frontside trench and laterally separated from the substrate by the passivation layer, wherein: the conductive material is electrically coupled with the substrate through the opening of the passivation layer to form a second contact, and the second contact is the other of either the cathode or the anode of the SPAD.

In various embodiments, a semiconductor device may include a substrate having a first surface and a second surface, wherein the first surface is one of either a frontside or a backside of the substrate, and the second surface is the other of the frontside or the backside of the substrate. The semiconductor device may include a first single-photon avalanche diode (SPAD) in the substrate and having a first contact proximate to the first surface of the substrate, wherein the first contact is one of either a cathode or an anode of the SPAD, and a second SPAD in the substrate and located next to the first SPAD. The semiconductor device may include a trench isolation structure in the substrate interposed between the first and second SPAD, comprising: a trench comprising a wide trench located proximate to the first surface of the substrate and a narrow trench extending through a bottom surface of the wide trench toward the second surface of the substrate wherein the trench comprises a transition region between the wide trench and the narrow trench, a continuous passivation layer lining the wide trench and the narrow trench, wherein the passivation layer includes an opening the transition region, and a conductive material disposed within the trench and laterally separated from the substrate by the passivation layer, wherein: the conductive material is electrically coupled with the substrate through the opening of the passivation layer to form a second contact and the second contact is the other of either the cathode or the anode of the SPAD.

In various embodiments, a method of forming a trench isolation structure between a first single-photon avalanche diode (SPAD) and a second SPAD in a substrate, wherein the substrate has a frontside and a backside and the first SPAD has a first electrical contact proximate to the frontside of the substrate, includes etching a frontside trench between the first SPAD and the second SPAD, forming a continuous passivation layer in the frontside trench, opening the continuous passivation layer at a horizontal surface of the frontside trench, and forming a conductive material in the frontside trench, wherein the conductive material is electrically coupled with the substrate through the opening of the passivation layer to form a second electrical contact.

These and other examples are described in increasing detail below.

### DETAILED DESCRIPTION

The following detailed description is intended to provide several examples that will illustrate the broader concepts that are set forth herein, but it is not intended to limit the invention or the application and uses of the invention. Furthermore, there is no intention to be bound by any theory presented in the preceding background or the following detailed description.

According to various embodiments, trench isolation structures may be located between neighboring pixels of an imaging device. The trench isolation structures may include a buried contact, whether anode or cathode, for the photo-detecting diode of one or more neighboring pixels. The buried contact may be referred to as an embedded contact. In some embodiments, the other of the anode or cathode may be located close to or at the frontside of the substrate and substantially centered within the pixel. In some embodiments, the photo-detecting diode may be a SPAD.

Some embodiments may include a stepped isolation trench having the contact in the stepped region. Some embodiments may include a frontside trench and a backside trench, and the backside trench may be segmented and/or overlapping with itself. Some embodiments may include a trench lined with a continuous passivation layer, where an opening in the continuous passivation layer allows a conductive material filling the trench to contact the substrate to form the buried contact.

Advantageously, devices and methods according to the present description have increased distance between the anode and cathode of the SPADs of each pixel, resulting in a lower risk of edge breakdown of the avalanche region of the respective SPADs. Devices and methods according to the present description provide for smaller pixel pitch and critical dimensions, thus increasing imager resolution and light detection performance, while still isolating neighboring pixels and preventing crosstalk and other undesired behaviors.

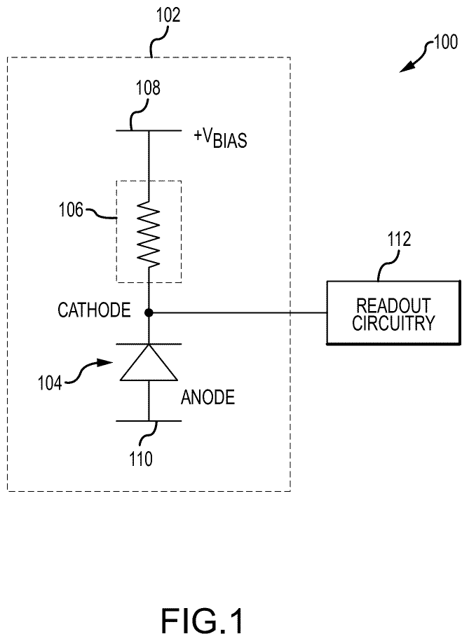

FIG. 1 illustrates an exemplary SPAD-based imager 100, also referred to herein as a SPAD imager 100. SPAD imagers 100 may be used in any number of exemplary systems. The SPAD imager 100 may be a sensor device having one or more single-photon avalanche diode (SPAD) devices 102 for detecting an incident photon. In some embodiments, the SPAD imager 100 may be a silicon photomultiplier device (SiPM) having a plurality of SPAD devices 102. A SPAD 104 may comprise a semiconductor diode and may be configured to receive incident photons. In some embodiments, the SPAD-based imager 100 may include one or more microlenses to further direct light into one or more SPADs 104 of the SPAD-based imager 100.

In some embodiments, a system using a SPAD imager 100 may include a LiDAR imaging system. The LiDAR imaging system may be a vehicular LiDAR system, for example for navigation, obstacle avoidance, ranging, or other safety functions. The LiDAR system may additionally or alternatively be a surveillance system, machine vision system, survey system, other ranging system, or any other suitable system.

The SPAD imager 100 may be included in other suitable systems and is not limited to the exemplary embodiments described herein. For example, a SPAD imager 100 may be included in other systems using light, for example visible light, near-infrared (near-IR) light, infrared (IR) light, or the like, to determine information about an environment in which the device is located.

An exemplary SPAD device 102 includes a SPAD 104 having a cathode and an anode biased by power supply voltage terminals 108 and 110, respectively. During operation of the SPAD device 102, voltage terminals 108 and 110 may reverse bias SPAD 104 to a voltage higher than the breakdown voltage. When reversed biased above the breakdown voltage, absorption of a single photon by the SPAD 104 can cause a large avalanche current in the SPAD 104 due to impact ionization.

The avalanche process in the SPAD 104 can, and in some cases will, continue indefinitely. While the avalanche current continues, subsequent photons incident on the SPAD 104 cannot be detected. In some embodiments, the avalanche process is stopped using quenching circuitry 106, which may include passive or active quenching. Quenching circuitry 106 can be used to lower the bias voltage of the SPAD 104 below breakdown level. In some embodiments, passive quenching circuitry 106 may include a resistor in series between the SPAD 104 cathode and a positive bias voltage terminal 108 as shown in FIG. 1. A SPAD 104 coupled in series with a quenching resistor or other quench circuitry 106 may be referred to as a microcell.

The avalanche current may produce an electrical signal that can be detected by readout circuitry 112. For example, initiation of the avalanche current due to detection of an incident photon by the microcell and subsequent quenching of the avalanche current may create a pulse current signal that the readout circuitry 112 can identify as a photon detection. The pulse current signal may be referred to herein as an avalanche pulse.

The readout circuitry 112 may process the detection of the current signal for a variety of purposes, for example counting the number of incident photons by counting the number of avalanche current pulses using analog or digital pulse counting circuits, and timing the laser time-of-flight (ToF) for determining a distance to the target. The example of FIG. 1 of the readout circuitry 112 coupled to a node between SPAD 104 and quenching circuitry 106 is merely illustrative. Readout circuitry 112 may be coupled to any suitable portion of the SPAD device 102. In some embodiments, the quenching circuitry 106 may be integrated with the readout circuitry 112.

A SPAD 104 must be quenched and reset for every initiated avalanche current. During the time required to quench and reset the SPAD 104, referred to as the dead time, no additional photons can be detected by the SPAD 104. The dead time therefore limits the number of photons detectable by the SPAD 104 for a given time period. In some embodiments, the dead time of a SPAD 104 may be on the order of nanoseconds, for example about 3 nanoseconds.

The SPAD 104 additionally has a chance of not generating an avalanche current in response to an incident photon. Accordingly, the SPAD 104 has a photon detection efficiency (PDE) that is a result of several factors, including a probability that a current carrier (electron and/or hole) is created when the SPAD 104 receives an incident photon, and a probability that the created current carrier initiates an avalanche current. For example, the SPAD 104 may have a PDE of about 30%, meaning the SPAD device 102 will detect about 30% of incident photons.

The SPAD imager 100, which may also be referred to herein as a SPAD-based semiconductor device 100, may include multiple SPAD devices 102 to increase the photon detection capability of the SPAD imager. In some embodiments, multiple SPAD devices 102 may be coupled in parallel (not shown) between the power supply voltage terminals 108 and 110 and may share a common readout circuitry 112. In some embodiments, each of the multiple SPAD devices 102 may have individual readout circuitry 112. In some embodiments, the SPAD devices 102 may be arranged as a one-dimensional or two-dimensional array, and the array may include tens, hundreds, thousands, tens of thousands (or more) SPAD pixels.

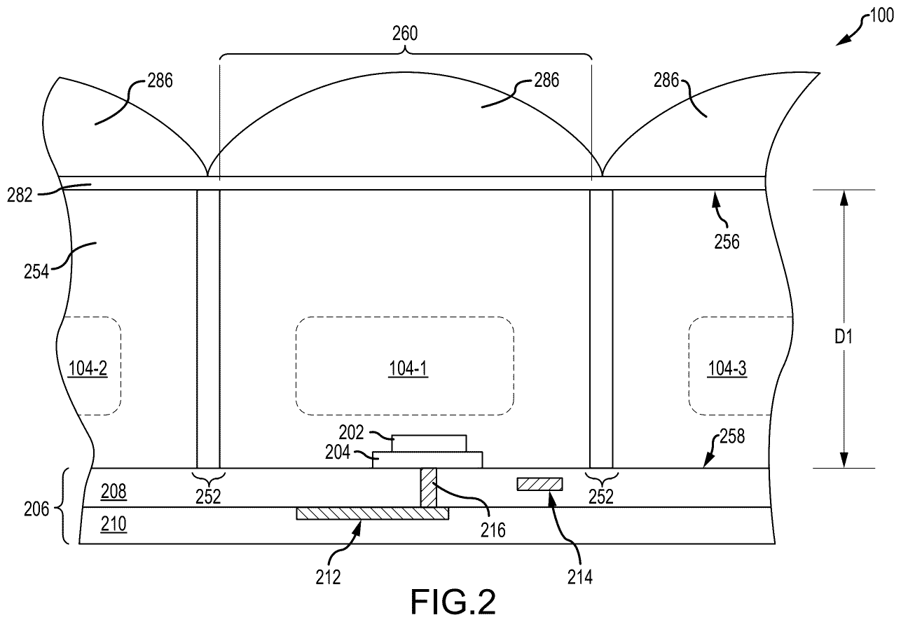

FIG. 2 is a cross-sectional side view of an illustrative SPAD-based semiconductor device 100 having multiple SPAD devices arranged in an array with each SPAD separated by isolation structures. The SPAD imager 100 includes a SPAD 104-1 that is adjacent to other SPADs of the imager, for example neighboring SPAD 104-2 and SPAD 104-3. Each SPAD may be part of a respective SPAD device 102, microcell, SPAD pixel 260, or the like. The SPAD imager 100 illustrated in FIG. 2 is a backside illuminated device (e.g., image sensor), wherein incident light passes through the back surface (BS) of the substrate 254. Embodiments according to the present disclosure may be suitably adapted to frontside illumination devices (e.g., image sensor).

The substrate 254 has a back surface 256 and a front surface (FS) 258. In some embodiments, for example in a backside imaging configuration, the FS 258 may be adjacent to a wiring layer 206. The wiring layer 206 may include one or more metallization layers having conductive signal lines 212, 214, for example formed from a metal, embedded in one or more dielectric layers 208, 210. The dielectric layers may be formed of any desired material, for example silicon dioxide, silicon nitride, an organic or inorganic material, or the like. Different layers of conductive signal lines 212, 214 may be coupled using conductive vias 216 through the one or more dielectric layers 208, 210.

In some embodiments, at least some of the wiring layer 206 may be included in a separate substrate that is attached, directly or indirectly, to substrate 254 during manufacturing. In some embodiments, the substrate 254 and one or more layers of the wiring layer 206 may be wafer bonded to the separate substrate. In some embodiments, the separate substrate may further include the readout circuitry 112 and/or other desirable circuitry and structures.

SPAD 104-1 may be formed in a substrate 254 that extends between the BS 256 and the FS 258. The substrate may include a semiconductor substrate formed from a material such as silicon. The substrate may have any suitable depth D1 measured between the BS 256 and the FS 258. In some embodiments, the depth D1 may be between 1 μm and 12 μm, for example between 2 μm and 9 μm, such as 3 μm or 6 μm. A SPAD pixel may have any suitable width, which may also be referred to herein as the pixel pitch. In some embodiments, the pixel pitch may be between 1 μm and 20 μm, between 1 μm and 10 μm, between 1 μm and 6 μm, for example 2 μm, 3 μm, or 6 μm.

A SPAD pixel 260 of the SPAD imager 100 may include the SPAD 104-1. The SPAD pixel 260 may include the portion of the substrate 254 in which the SPAD 104-1 is located, for example the portion of the substrate 254 between the FS 258 and BS 256 and surrounded by isolation structures 252. The SPAD pixel 260 may include other components and connections of the SPAD device 102, for example the quenching circuitry 106 (not shown). The SPAD pixel 260 may include other similarly located and related structures, for example respective doped regions 202, 204, respective portions of the wiring layer 206, and/or other features formed within the substrate within the respective isolation structures 252 and between the FS 258 and BS 256.

In some embodiments, the substrate 254 may be formed by a p-type doped semiconductor layer, for example p-type doped epitaxial silicon. The SPAD 104-1 may be formed by the p-type doped semiconductor layer, a p-type doped enrichment layer 202, and an n-type doped region 204. The n-type doped region 204 may function as the cathode for SPAD 104-1. The cathode and anode (not shown) of each SPAD pixel 260 may be coupled by conductive vias 216 to respective portions of the wiring layer 206. The doping types of the p-type regions and the n-type regions described herein may be reversed if desired.

One or more microlenses 286 may be formed over SPADs 104-1, 104-2, 104-3. The microlenses 286 may focus light toward the respective SPADs 104-1, 104-2, 104-3. A planarization layer 282 may optionally be formed between the microlenses 286 and the BS 256 of the substrate 254. The planarization layer 282 may be formed from any suitable material or combination of materials, for example one or more oxide layers such as silicone dioxide, silicon nitride, or the like.

Still referring to FIG. 2, SPAD 104-1 may be isolated from adjacent SPADs by isolation structures 252 in the substrate 254. Adjacent SPADs 104-1, 104-2, 104-3 may also be referred to herein as neighboring SPADs, and adjacent pixels 260 may also be referred to herein as neighboring pixels. To mitigate crosstalk and/or achieve other performance goals, the isolation structures 252 may be formed partially or completely around each SPAD 104-1, 104-2, 104-3. For example, the isolation structures 252 may be formed along one or more sides of each SPAD pixel 260. A side of a SPAD pixel 260 may include the substantially linear region between a first SPAD 104-1 and a second adjacent SPAD 104-2. A corner of a SPAD pixel 260 may include the region where at least three SPAD pixels 260 abut.

The isolation structures 252 may include trench structures formed from the FS 258 and/or BS 256. A trench formed from the FS 258 may be referred to herein as a FS trench, and a trench formed from the BS 256 may be referred to herein as a BS trench. In some embodiments, the isolation structures 252 may include deep trench isolation structures that extend partially or fully through the substrate 254.

The isolation structures 252 may be filled with different materials that perform various desired functions. The isolation structures 252 may include a light absorbing material filler that absorbs photons and prevents photons, for example generated by an avalanche, from passing to a neighboring microcell and causing crosstalk. In some embodiments, the light absorbing material includes a metal, such as tungsten.

The isolation structures 252 may include a conductive material, such as metal, polysilicon, and/or the like, to provide a conductive path to one or more SPADs as described in more detail below. In some embodiments, the conductive material may include tungsten, polysilicon, and/or the like. In some embodiments, the conductive material may include multiple conductive materials, for example tungsten toward the FS 258 and polysilicon toward the BS 256. For further example, approximately the top third of the isolation structure 252 proximate to the FS 258 may include tungsten and the remaining approximately two-thirds of the isolation structure 252 may include polysilicon.

The isolation structures may include a low-index of refraction material that causes total internal reflection. The low-index material may reflect photons, keeping them within the active region of the SPAD 104-1 to increase efficiency. In some embodiments, the low-index material may include silicon dioxide or the like.

The isolation structures 252 may include a high dielectric constant (hi-k) material, for example formed in a trench in the substrate 254, to mitigate dark current. In some embodiments, the hi-k material may include an oxide coating, for example aluminum oxide, hafnium oxide, tantalum oxide, and/or the like. The isolation structures 252 may include a passivation layer, which may perform various desired functions such as mitigating dark current, isolating a conductive material filler from the substrate 254, reflecting photons, and/or the like. The passivation layer may include any suitable material, for example an oxide such as a hi-k material, silicon dioxide, silicon nitride, other dielectric, and/or the like.

In some embodiments, the portion of the isolation structures 252 closer to the FS 258 may include a light absorbing material such as a metal filler. The cathode and/or anode contact for SPAD 104-1 may be adjacent to the front surface 258, and the origin point of photon emissions, for example due to avalanche, may be primarily adjacent to the FS 258. The portions of the isolation structures 252 that are adjacent to the FS 258 may receive the emitted photons at or about orthogonal angles. The light absorbing material may be positioned in the isolation structures 252 suitably toward the FS 258 to block most or all emitted photons and prevent crosstalk.

In some embodiments, a portion of the isolation structures 252 further from the FS 258 may include a low-index material. Portions of the isolation structures 252 further from the FS 258 may receive emitted photons at higher angles of incidence, and the low-index material may reflect the light as discussed above, preventing it from passing to neighboring SPADs 104-2, 104-3.

Embodiments of isolation trench structures 252 described herein increase the distance between the first and second SPAD contacts, that is, between the anode and cathode of the SPAD 104-1. Some embodiments of isolation trench structures 252 described herein generally include a first SPAD contact, whether anode or cathode, as part of the trench isolation structures 252, and a second SPAD contact, the other of the anode or cathode, at or near the FS 258 and approximately centered within the SPAD pixel 260. In several embodiments, the first SPAD contact is substantially contained within the boundaries of the isolation trench 252 within the substrate. For example, the first SPAD contact may not extend outside the lateral isolation trench 252 boundaries.

The first SPAD contact is thus located further horizontally (laterally) from the second contact compared to locating the first SPAD contact within the bulk substrate 254 between the isolation structures 252. Some embodiments of the isolation trench structures 252 described herein locate the first SPAD contact vertically away from the FS 258, that is, part or all the way to the BS 256. Increasing the horizontal and/or vertical distance between the anode and cathode decreases the strength of the electric field and decreases the risk of edge breakdown of the SPAD 104-1. A SPAD contact located substantially in the isolation trench 252 within the substrate may be referred to herein as a buried contact.

Embodiments of isolation trench structures 252, which may be referred to herein as trenches 252, trench structures 252, or isolation structures 252, may include the trenches 252 surrounding each SPAD pixel 260. While embodiments described below discuss the anode contact of the SPAD as being located within the trenches 252 (the first SPAD contact), it will be recognized that the cathode may alternatively be located within the trenches 252.

### First Subset of Exemplary Embodiments

Next, a first subset of embodiments of forming an improved trench isolation structure 252 will be described. The first subset of embodiments include a FS trench lined with a passivation layer and filled with a conductive material, where the passivation layer at the bottom of the FS trench (portion of trench facing BS 256) is open to allow a conductive coupling between the conductive material and the substrate 254. The bottom of the FS trench may be unlined with the passivation layer.

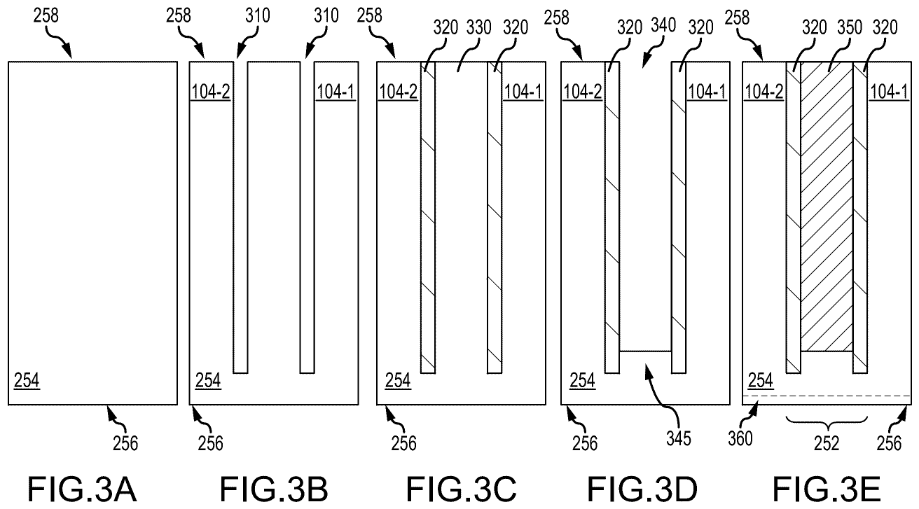

Referring to FIGS. 3A-E, the first subset of trench isolation embodiments may include some first exemplary embodiments having a conductive material located between annular trenches and electrically coupled with the substrate 254 at the bottom of the trench structure 252.

Referring to FIG. 3A, the FS surface 258 of the substrate 254 may be patterned with a photoresist in preparation for etching an annular trench. Photoresist and photoresist processes are not shown in any figure included herein for the sake of clarity but will be understood. Referring to FIG. 3B, one or more annular trenches 310 may be etched through the substrate. Each annular trench 310 may partially or fully surround a respective SPAD pixel 260.

The annular trenches 310 may be etched to any suitable distance through the substrate 254, for example more than halfway through the substrate 254, halfway through the substrate 254, or less than halfway through the substrate 254. In some embodiments, after etching the annular trenches 310, the photoresist may be stripped.

Referring to FIG. 3C, a passivation layer 320 may be deposited in the etched annular trenches 310. The passivation layer 320 may be a conformal passivation layer. The substrate 254 may be patterned with a photoresist suitable for etching the central portion 330 of the substrate 254 between neighboring passivation layers 320.

Referring to FIG. 3D, the central portion 330 may then be etched to any suitable distance through the substrate 254 to form a central trench 340. In some embodiments, the central portion 330 may be etched to the same depth as the annular trenches 310, to a lesser depth than the annular trenches 310, for example as shown in FIG. 3D, or to a greater depth than the annular trenches 310. In some embodiments, after etching the central portion 330, the photoresist may be stripped.

In some embodiments, the portion 345 of the substrate at the bottom of the central trench 340 may be doped, for example implanted with charged ions, to facilitate conductive coupling with a conductive material to be deposited in the central trench 340. In some embodiments, ion implantation may be used, for example implanting single-charged positive ions, double-charged positive ions, and/or the like. For example, the substrate 254 may be suitably patterned and a positive ion implant performed, after which the photoresist may be stripped. The ion implant may then be activated, for example by annealing at a suitable temperature for a suitable amount of time (not shown).

Referring to FIG. 3E, a conductive material 350 may be deposited in the central trench 340. In some embodiments, the conductive material 350 may also be deposited on the FS surface 258 of the substrate 254, which may then be patterned and etched as part of the wiring layer 206 (not shown). The conductive material 350 may be coupled through one or more conductive signal lines 212, 214 to appropriate circuitry of the SPAD imager 100 to form the first contact for one or more adjacent SPADs 104-1, 104-2. The conductive material 350 may for example include tungsten.

In some embodiments, the substrate 254 may include an etch stop 360 proximate to the BS 256. After processing from the FS 258, the FS 258 may be attached to a carrier wafer to allow subsequent processing from the BS 256. The substrate may be etched down to the etch stop 360, for example to obtain the desired depth D1 of the substrate. In some embodiments, the substrate may be thinned from the BS 256 to approximately 6 μm for detecting IR or near-IR photons. Various structures may them be formed from the backside, for example one or more BS trenches.

Any of the embodiments taught herein may include an etch stop 360 and backside processing, even if not specifically described with respect to any particular embodiment. Therefore, some of the structures shown and described herein may, in some embodiments, have a small portion of the structures near the BS 256 removed during a subsequent etch.

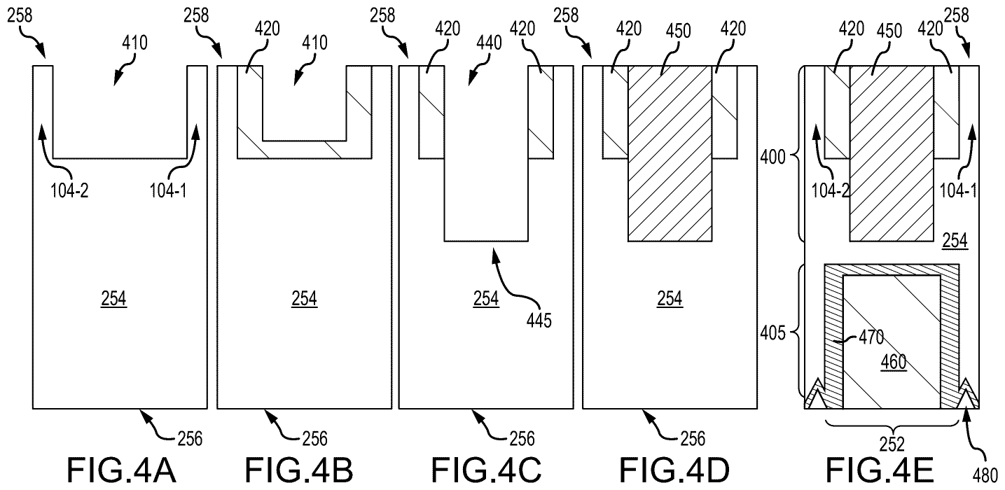

Referring to FIGS. 4A-E, the first subset of trench isolation embodiments may include some second exemplary embodiments having a trench structure 252 that may partially or fully extend along one or more edges of one or more SPAD pixels 260. The trench structure 252 may include a FS trench structure 400 and a BS trench structure 405.

Referring to FIG. 4A, an FS trench 400 may be formed by patterning the FS surface 258 of the substrate 254 with a photoresist in preparation for etching a wide trench. The wide trench 410 may then be etched through the substrate 254. The wide trenches 410 may be etched to any suitable distance through the substrate 254, for example more than halfway through the substrate 254, halfway through the substrate 254, or less than halfway through the substrate 254. In some embodiments, after etching the wide trench 410, the photoresist may be stripped.

Referring to FIG. 4B, a passivation layer 420 may be deposited in the wide trench 410. The passivation layer 420 may be a conformal passivation layer. Referring to FIG. 4C, the substrate 254 may be patterned with a photoresist suitable for etching a narrow trench 440 though the wide trench 410. The narrow trench 440 may then be etched to any suitable distance through the substrate 254, for example leaving at least some of the passivation layer 420 on the sidewalls of the wide trench 410. In some embodiments, the narrow trench 440 may be etched to a greater depth than the wide trench 410.

In some embodiments, the portion 445 of the substrate at the bottom of the narrow trench 440 may be doped, for example implanted with charged ions, to facilitate conductive coupling with a conductive material to be deposited in the narrow trench 440. In some embodiments, ion implantation may be used, for example implanting single-charged positive ions, double-charged positive ions, and/or the like. In some embodiments, the same photoresist used to etch the narrow trench 440 may be used for the ion implantation because it is self-aligned and/or because it may be a low energy implant having a shallow depth. In other embodiments, the substrate 254 may be separately patterned for the ion implantation. The one or more photoresists may be suitably stripped, and the ion implant may then be activated as described above.

Referring to FIG. 4D, a conductive material 450 may be deposited in the narrow trench 440. In some embodiments, the conductive material 450 may also be deposited on the FS surface 258 of the substrate 254 (not shown), which may then be patterned and etched as part of the wiring layer 206 (not shown). The conductive material 450 may be coupled through one or more conductive signal lines 212, 214 to appropriate circuitry of the SPAD imager 100 to form the first contact for one or more adjacent SPADs 104-1, 104-2. The conductive material 450 may for example include tungsten.

Referring to FIG. 4E, a BS trench 405 may be formed from the BS surface 256, for example a partial BS deep trench. The trench structure 252 may include both the BS trench 405 and the FS trench 400.

In some embodiments, the BS trench 405 may include a passivation layer. In some embodiments, the BS trench 405 may be lined with a hi-k dielectric 470 and filled with a passivation layer 460, for example silicon dioxide. In some embodiments, the BS trench 405 does not contact the FS trench 400 structures, such as the passivation layer 420 and conductive material 450, and may leave a conductive path between the conductive material 450 and one or more neighboring SPADs 104-1, 104-2.

The BS trench 405 may be formed adjacent to pyramid light scattering structures 480 for the neighboring SPADs 104-1, 104-2. The light scattering structures 480 may be configured to increase the path length of photons for the purpose of detecting longer wavelength light such as IR or near-IR. The BS trench 405 may be included, in some embodiments, for the purpose of preventing light leakage (which may be referred to as crosstalk) from one 260 to another due to scattering from the light scattering structures 480, due to generated photons during an avalanche of a respective SPAD pixel 260, among other desired purposes.

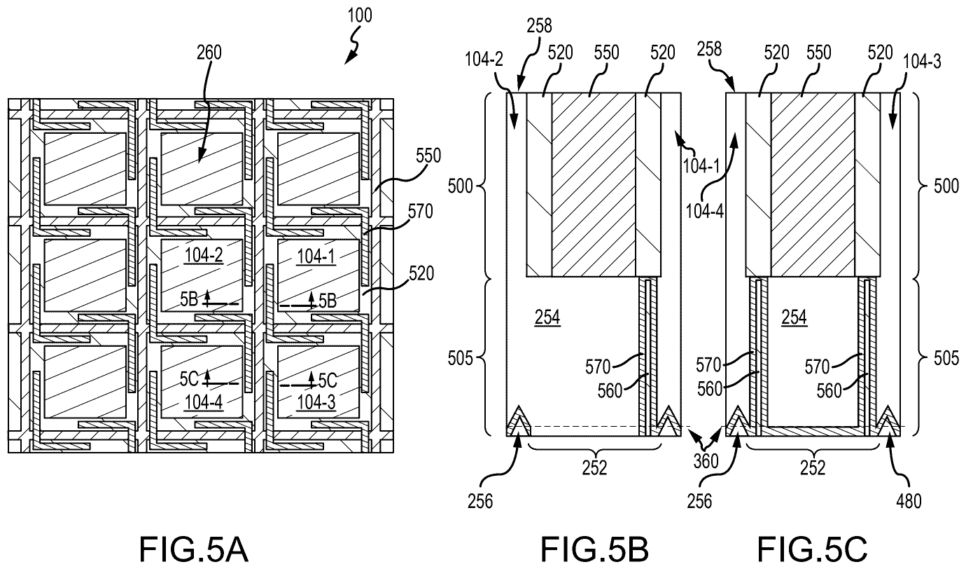

Referring to FIGS. 5A-C, the first subset of trench isolation embodiments may include some third exemplary embodiments having a trench structure 252 that may partially or fully extend along one or more edges of one or more SPAD pixels 260. The trench structure 252 may include a FS trench structure 500 and a BS trench structure 505. In some embodiments, the trench structure 252, for example the BS trench structure 505, may include multiple separate segments of a BS trench that are overlapped to provide both varying conductive paths to the SPADs 104-1, 104-2, 104-3, 104-4 as well as light blocking. The BS trench 505 may be a deep trench, and may connect to the FS trench 500.

FIG. 5A representatively illustrates the relative horizontal arrangement of the various components of the trench structure 252 without consideration of the vertical locations of such structures. FIGS. 5B and 5C illustrate the relative vertical arrangement of the various components of the trench structure.

Referring to FIG. 5A, the array of SPADs 104-1, 104-2, 104-3, 104-4 may include a conductive material 550 surrounding the pixels 260 in a FS trench 500 lined with a passivation layer 560, and may include a segmented BS trench 505 including a hi-k material 570 and/or a passivation layer 560. The FS trench 500 may be formed, for example, using the similar or same methods as described with respect to the FS trench 400 illustrated by FIGS. 4A-4E.

Referring to FIG. 5B, which is a first cross-section as referenced in FIG. 5A, a first portion of the segmented BS trench 505 may include a passivation layer 560 and/or hi-k material 570 that contacts or otherwise connects to the bottom of the FS trench 500 on one side of the trench structure 252. The BS trench 505 may specifically connect to the passivation layer 520 of the FS trench 500 on the same side of the trench structure 252. The portion of the BS trench 505 that includes only one side of the passivation layer 560 and/or hi-k material 570 as shown in FIG. 5B may be referred to as a single-sided segmented BS trench.

As shown in FIG. 5A, in some embodiments a single-sided segmented BS trench may cross, in a horizontal direction, the conductive material 550 of the FS trench 500 such that the passivation layer 560 and/or hi-k material 570 of the single-sided segmented BS trench is adjacent to two SPADs, for example SPADs 104-1 and 104-2. In some alternative embodiments, the passivation layer 560 and/or hi-k material 570 of the single-sided segmented BS trench may remain adjacent to a single SPAD and may not cross the conductive material 550 of the FS trench 500. Either arrangement may provide overlapping single-sided BS trenches 505.

A conductive path remains provided from the conductive material 550 to the SPAD 104-2 on the opposite side of the trench structure 252, and no conductive path is provided from the conductive material 550 to the other neighboring SPAD 104-1. Each SPAD 104-1, 104-2, 104-3, 104-4 may be provided with a conductive path between the conductive material 550 and the respective SPAD at respective first portions of the BS trench 505. The conductive material 550 may for example include tungsten.

Referring to FIG. 5C, which is a second cross-section as referenced in FIG. 5A, a second portion of the segmented BS trench 505 may include a passivation layer 560 and/or hi-k material 570 that contacts or otherwise connects to the bottom of the FS trench 500 on both sides of the trench structure 252. The BS trench 505 may specifically connect to the passivation layers 520 of the FS trench 500 on both sides of the trench structure 252. In some embodiments, the second portion of the BS trench 505 may include two backside deep trenches coated with a hi-k material and filled with an oxide, with each backside deep trench connecting to a respective passivation layer 520 of the FS trench 500 and leaving substrate 254 between the two backside deep trenches.

The second portion of the segmented BS trench 505 may block a directly lateral conductive path to each neighboring SPAD 104-3, 104-4. The second portion of the segmented BS trench 505, which may be formed from partially overlapping multiple first portions of the BS trench 505, may function to prevent some or all light leakage between neighboring pixels 260.

In some embodiments, the BS trench 505 may include a passivation layer 560. In some embodiments, the BS trench 505 may be lined with a hi-k dielectric 570 and filled with a passivation layer 560, for example silicon dioxide. The BS trench 505 may be formed adjacent to pyramid light scattering structures 480 for the neighboring SPADs 104-1, 104-2, 104-3, 104-4, as described with respect to other embodiments above. In some embodiments, the substrate 254 may include an etch stop 360 as described above. BS trenches 505 may be suitably adapted to the other exemplary embodiments described herein.

### Second Subset of Exemplary Embodiments

Next, a second subset of embodiments of forming an improved trench isolation structure 252 will be described. The second subset of embodiments include a multi-width FS trench lined with a passivation layer having an opening at the transition between a first and second width of the FS trench. The opening allows a conductive material filler in the trench structure 252 to conductively couple with the substrate 254 and form the first contact of the SPAD 104-1. In some embodiments, the bottom of the FS trench may be unlined with the passivation layer to allow a second conductive coupling of the conductive filler material with the substrate 254.

The opening in the passivation layer at the transition between the first and second widths of the FS trench may be an opening in an otherwise continuous passivation layer, for example formed in a same deposition step rather than in separate deposition steps to form the passivation layer separately for each width. Thus, the substrate 254 may be exposed to the conductive filler material at the stepped region of the stepped trench. The multi-width FS trench may be referred to as a stepped trench, and the transition region between the first and second widths of the FS trench may be referred to as a stepped region.

More generally, a horizontal surface or region of a trench structure 252 may include the surface or portion of the trench structure 252 located between two vertical walls of the trench structure, where the vertical walls run substantially perpendicular to the FS 258 and/or BS 256. In some embodiments, the horizontal surface or region is determined by one or more etching steps, and so the resulting horizontal region or surface may or may not be substantially flat and perpendicular to the vertical walls, depending on the particular processes used. In some embodiments, the bottom of a FS trench or BS trench may be a horizontal surface or region of the trench structure 252. In some embodiments, the transition region may include a horizontal surface or region located between the vertical walls of the wide trench and the narrow trench.

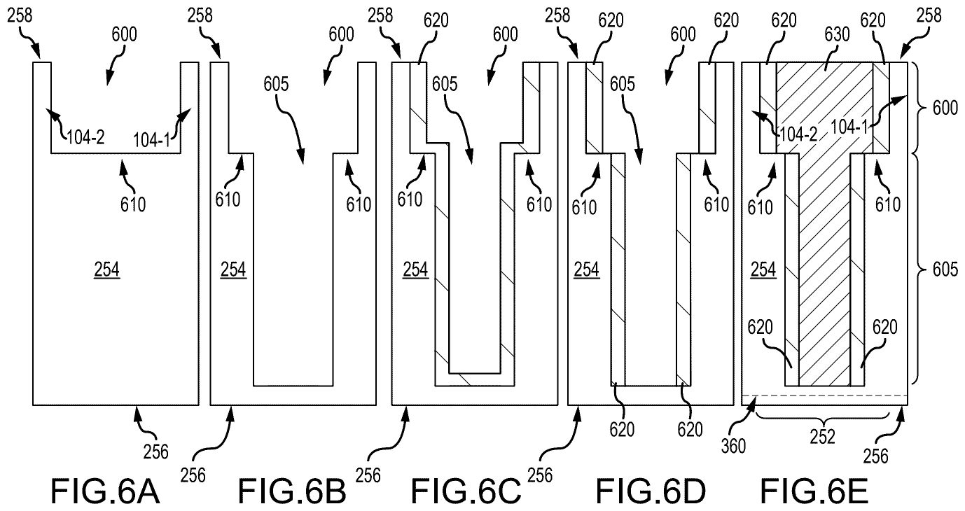

Referring to FIGS. 6A-E, the second subset of trench isolation embodiments may include some fourth exemplary embodiments having a trench structure 252 that may partially or fully extend along one or more edges of one or more SPAD pixels 260. The trench structure 252 may include a stepped FS trench having a wide trench 600 and a narrow trench 605 lined with a passivation layer, wherein the passivation layer is open at a transition region to allow electrical coupling of a conductive material filler with the substrate 254.

Referring to FIG. 6A, a wide FS trench 600 may be formed by patterning the FS surface 258 of the substrate 254 with a photoresist in preparation for etching a wide trench. The wide trench 600 may then be etched through the substrate 254. The wide trench 600 may be etched to any suitable distance through the substrate 254, for example more than halfway through the substrate 254, halfway through the substrate 254, or less than halfway through the substrate 254. In some embodiments, after etching the wide trench 600, the photoresist may be stripped.

In some embodiments, the portion 610 of the substrate at the bottom of the wide trench 600 may be doped, for example implanted with charged ions, to facilitate conductive coupling with a conductive material to be deposited in the trench 252. In some embodiments, ion implantation may be used as described above. In some embodiments, the same photoresist used to etch the wide trench 600 may be used for the ion implantation prior to stripping the photoresist, because it is self-aligned and/or because it may be a low energy implant having a shallow depth. In other embodiments, the substrate 254 may be separately patterned for the ion implantation, for example allowing ion implantation only in the wide trench 600. The one or more photoresists may be suitably stripped, and the ion implant may then be activated as described above.

Referring to FIG. 6B, a narrow trench 605 may be etched through the wide trench 600. Appropriate patterning of a photoresist may be applied, and the narrow trench 605 may then be etched through the substrate 254. The narrow trench 605 may be etched to any suitable distance through the substrate 254. In some embodiments, the narrow trench 605 may be etched to have a depth equal to one to five time the depth of the wide trench 600, for example from two to four times the depth of the wide trench 600. In some embodiments, the narrow trench 605 is formed with a depth approximately twice that of the wide trench 600. In some embodiments, after etching the narrow trench 605, the photoresist may be stripped.

Referring to FIG. 6C, a passivation layer 620 may be deposited in both the wide trench 600 and narrow trench 605. The passivation layer 620 may be an uninterrupted and non-discontinuous conformal passivation layer, for example formed simultaneously, in a single deposition, or the like. Referring to FIG. 6D, the continuous passivation layer 620 may then be opened at the transition between the narrow trench 605 and wide trench 600.

In some embodiments, the passivation layer 620 may be etched away at the transition region. For example, a spacer etch may be performed to remove some or all of the passivation layer 620 from the horizontal trench surfaces. In some embodiments, the passivation layer may be removed from the bottom of the narrow trench 605. In some such embodiments, the portion of the substrate 254 exposed at the bottom of the narrow trench 605 may then be doped, for example with ion implantation as described above.

Referring to FIG. 6E, a conductive material 630 may be deposited in the wide trench 600 and narrow trench 605. The conductive material 630 may be in electrical contact with the substrate 254 in the transition region between the narrow trench 605 and wide trench 600, and in some embodiments also through the bottom of the narrow trench 605. The conductive material 630 may for example include tungsten.

In some embodiments, the conductive material 630 may also be deposited on the FS surface 258 of the substrate 254 (not shown), which may then be patterned and etched as part of the wiring layer 206 (not shown). The conductive material 630 may be coupled through one or more conductive signal lines 212, 214 to appropriate circuitry of the SPAD imager 100 to form the first contact for one or more adjacent SPADs 104-1, 104-2, for example at the stepped region on one or both sides of the isolation trench 252, and in some cases also through the bottom of the narrow trench 605.

Embodiments of the fourth exemplary embodiments that have an electrical contact between the conductive material 630 and the substrate 254 at the bottom of the narrow trench are also examples of embodiments of the first subset of trench isolation embodiments.

In some embodiments, the substrate 254 may include an etch stop 360 proximate to the BS 256. After processing from the FS 258, the FS 258 may be attached to a carrier wafer to allow subsequent processing from the BS 256. The substrate may be backside etched down to the etch stop 360. In some embodiments, the substrate is backside etched down to the narrow trench 605, and in some embodiments the backside etch stops prior to reaching the narrow trench 605.

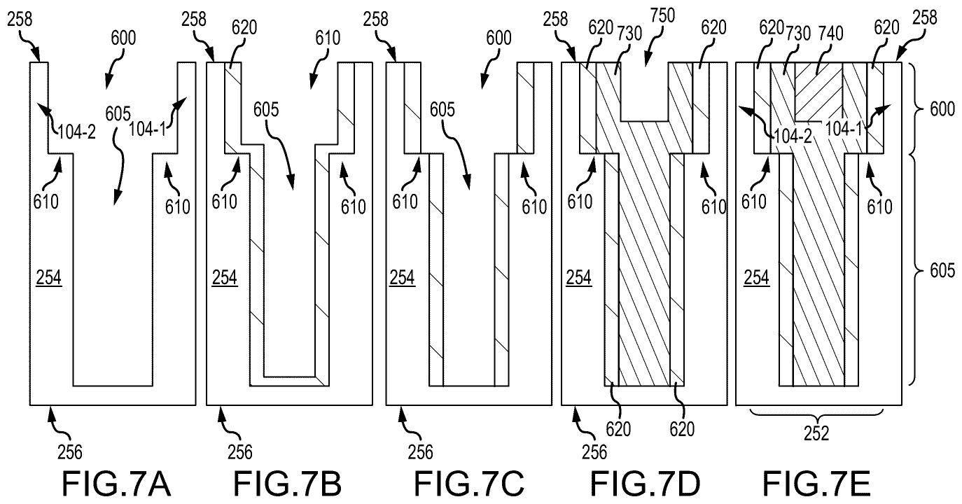

Referring to FIGS. 7A-E, the second subset of trench isolation embodiments may include some fifth exemplary embodiments having a trench structure 252 that may partially or fully extend along one or more edges of one or more SPAD pixels 260. The trench structure 252 may include a stepped FS trench having a wide trench 600 and a narrow trench 605 lined with a passivation layer, wherein the passivation layer is open at a transition region to allow electrical coupling of a conductive material filler with the substrate 254. A trench structure 252 according to the fifth exemplary embodiments may be an alternative embodiment of the fourth exemplary embodiments, having multiple conductive materials within the trench structure 252.

Referring to FIG. 7A, as described with respect to the fourth exemplary embodiments, a wide trench 600 may be formed in the substrate 254, the bottom portion 610 of which may be doped as described above, and then a narrow trench 605 may be formed at the bottom of the wide trench 600.

Referring to FIGS. 7B and 7C, also as described with respect to the fourth exemplary embodiments, a passivation layer having an opening at the transition region may be formed. For example, a passivation layer 620 may be deposited in both the wide trench 600 and narrow trench 605. The passivation layer 620 may be a conformal passivation layer formed in a single deposition. In some embodiments, the continuous passivation layer 620 may be etched away at the transition region. For example, a spacer etch may be performed to remove some or all of the passivation layer 620 from the horizontal trench surfaces, for example removing enough to allow contact of a conductive filler material.

In some embodiments, the passivation layer may be removed from the bottom of the narrow trench 605, for example by the spacer etch. In some such embodiments, the portion of the substrate 254 exposed at the bottom of the narrow trench 605 may then be doped, for example with ion implantation as described above.

Referring to FIG. 7D, a first conductive material 730 may be deposited in the wide trench 600 and narrow trench 605. The first conductive material 730 may be in electrical contact with the substrate 254 in the transition region between the narrow trench 605 and wide trench 600, and in some embodiments also through the bottom of the narrow trench 605. The first conductive material 730 may include polysilicon. In some embodiments, the narrow trench 605 may be filled with polysilicon and the wide trench 600 coated with polysilicon, for example in the same process step. The polysilicon may not completely fill the wide trench 600, for example leaving a cavity 750 within the polysilicon.

Referring to FIG. 7E, a second conductive material 740 may be deposited within the first conductive material 730 within the wide trench 600, for example within the cavity 750. In some embodiments, the first conductive material 730 may be etched or otherwise processed to modify the shape of the cavity 750. The second conductive material 740 may for example include tungsten.

In some embodiments, the second conductive material 740 may also be deposited on the FS surface 258 of the substrate 254 (not shown), which may then be patterned and etched as part of the wiring layer 206 (not shown). The second conductive material 740 may be coupled through one or more conductive signal lines 212, 214 to appropriate circuitry of the SPAD imager 100 to form, in combination with the first conductive material 730, the first contact for one or more adjacent SPADs 104-1, 104-2. For example, the first contact may be at the stepped region on one or both sides of the isolation trench 252, and in some cases also through the bottom of the narrow trench 605.

Embodiments of the fifth exemplary embodiments that have an electrical contact between the conductive material 730 and the substrate 254 at the bottom of the narrow trench are also examples of embodiments of the first subset of trench isolation embodiments.

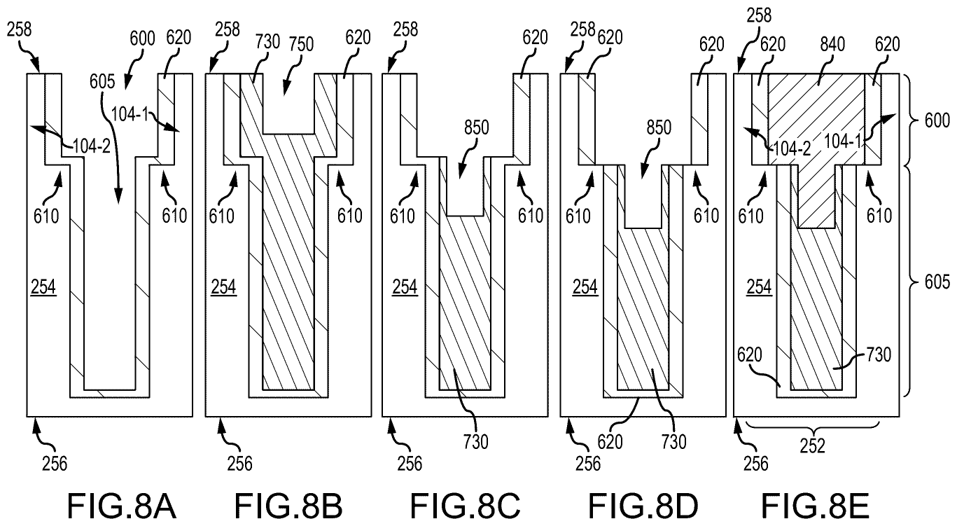

Referring to FIGS. 8A-E, the second subset of trench isolation embodiments may include some sixth exemplary embodiments having a trench structure 252 that may partially or fully extend along one or more edges of one or more SPAD pixels 260. The trench structure 252 may include a stepped FS trench having a wide trench 600 and a narrow trench 605 lined with a passivation layer, wherein the passivation layer is open at a transition region to allow electrical coupling of a conductive material filler with the substrate 254. A trench structure 252 according to the sixth exemplary embodiments may be an alternative embodiment of the fourth and/or fifth exemplary embodiments, having multiple conductive materials within the trench structure 252 with the second conductive material contacting the substrate 254 in the transition region.

Referring to FIG. 8A, as described with respect to the fifth exemplary embodiments, a wide trench 600 may be formed in the substrate 254, the bottom portion 610 of which may be doped as described above, and then a narrow trench 605 may be formed at the bottom of the wide trench 600. The wide trench 600 and narrow trench 605 may be lined with a conformal passivation layer 620 as also described with respect to the fifth exemplary embodiments.

Referring to FIG. 8B, as similarly described with respect to the fifth exemplary embodiments, a first conductive material 730 may be deposited in the wide trench 600 and narrow trench 605. The first conductive material 730 may include polysilicon. In some embodiments, the narrow trench 605 may be filled with polysilicon and the wide trench 600 coated with polysilicon, for example in the same process step. The polysilicon may not completely fill the wide trench 600, for example leaving a cavity 750 within the polysilicon.

Referring to FIG. 8C, in some embodiments, a photoresist may be patterned to suitably etch the first conductive material 730 from the wide trench 600. The first conductive material 730 may be etched from the wide trench 600, for example completely removing it from the wide trench 600. The etch may create a second cavity 850 in the first conductive material 730 in the narrow trench 605. The photoresist may be removed as desired.

Referring to FIG. 8D, the continuous passivation layer 620 may be etched away at the transition region. For example, a spacer etch may be performed to remove some or all of the passivation layer 620 from the horizontal trench surfaces, for example removing enough to allow contact of a conductive filler material. In some embodiments, for example having polysilicon as the first conductive material 730, the bottom of the second cavity 850 may also be etched.

Referring to FIG. 8E, a second conductive material 840 may be deposited within the wide trench 600. In some embodiments, the second conductive material may also be deposited within the first conductive material 730 within the narrow trench 605, for example within the second cavity 850. The second conductive material 840 may be in electrical contact with the substrate 254 in the transition region between the narrow trench 605 and wide trench 600, through the opening in the passivation layer 620. The second conductive material 840 may for example include tungsten.

In some embodiments, the second conductive material 840 may also be deposited on the FS surface 258 of the substrate 254 (not shown), which may then be patterned and etched as part of the wiring layer 206 (not shown). The second conductive material 840 may be coupled through one or more conductive signal lines 212, 214 to appropriate circuitry of the SPAD imager 100 to form the first contact for one or more adjacent SPADs 104-1, 104-2. For example, the first contact may be at the stepped region on one or both sides of the isolation trench 252.

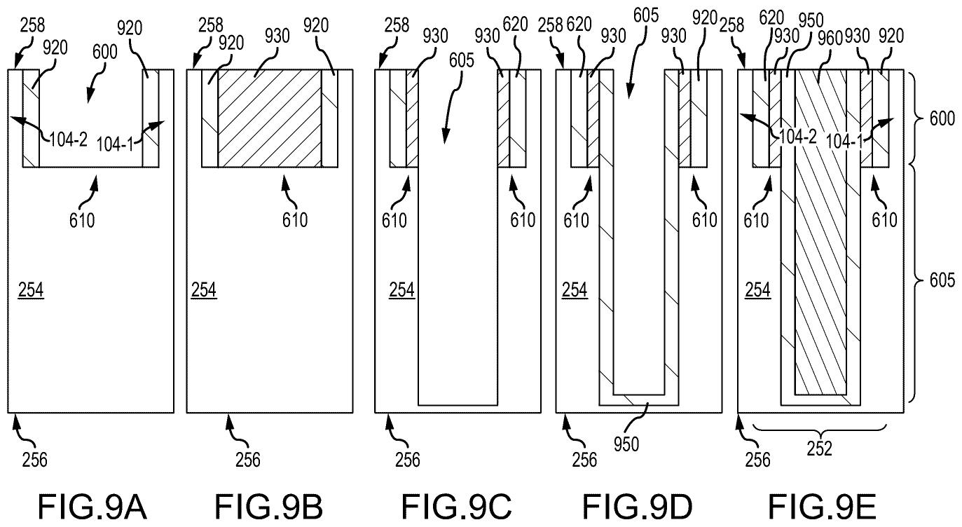

Referring to FIGS. 9A-E, the second subset of trench isolation embodiments may include some seventh exemplary embodiments having a trench structure 252 that may partially or fully extend along one or more edges of one or more SPAD pixels 260. The trench structure 252 may include a stepped FS trench having a wide trench 600 and a narrow trench 605, each lined with a passivation layer, wherein a separation of the passivation layers at a transition region allows electrical coupling of a conductive material filler with the substrate 254. Some trench structures 252 according to the seventh exemplary embodiments may for example be variations of the second exemplary embodiments and/or sixth exemplary embodiments, having a separate narrow FS trench formed though the conductive material.

Referring to FIG. 9A, as described with respect to the sixth exemplary embodiments, a wide trench 600 may be formed in the substrate 254, the bottom portion 610 of which may be doped as described above. In some seventh exemplary embodiments, a first passivation layer 920 may be formed in the wide trench 600. As described above, the first passivation layer 920 may be a deposited conformal passivation layer.

The passivation layer 920 may be removed at the bottom of the wide trench 600. For example, a spacer etch may be performed to remove some or all of the passivation layer 920 from the horizontal trench surfaces, for example removing enough to allow contact of a conductive filler material with the substrate 254. In other embodiments, the passivation layer 920 may be formed sidewalls of the wide trench 600 without forming the passivation layer on the bottom of the wide trench 600. Formation of the passivation layer 920 and doping the bottom portion 610 of the wide trench 600 may occur in any suitable ordering.

Referring to FIG. 9B, a conductive material 930 may be deposited in the wide trench 600. The conductive material 930 may be in electrical contact with the substrate 254 at the bottom of the wide trench 600. The conductive material 930 may for example include tungsten. In some embodiments, the conductive material 930 may also be deposited on the FS surface 258 of the substrate 254 (not shown), which may then be patterned and etched as part of the wiring layer 206 (not shown). The conductive material 930 may be coupled through one or more conductive signal lines 212, 214 to appropriate circuitry of the SPAD imager 100 to form the first contact for one or more adjacent SPADs 104-1, 104-2.

Referring to FIG. 9C, a narrow trench 605 may be etched through the conductive material 930 in the wide trench 600. Appropriate patterning of a photoresist may be applied, and the narrow trench 605 may then be etched through the conductive material 930 and substrate 254. The narrow trench 605 may be etched to any suitable distance through the substrate 254.

In some embodiments, the narrow trench 605 may be etched to have a depth equal to one to five time the depth of the wide trench 600, for example from two to four times the depth of the wide trench 600. In some embodiments, the narrow trench 605 is formed with a depth approximately twice that of the wide trench 600. In some embodiments, after etching the narrow trench 605, the photoresist may be stripped.

Referring to FIG. 9D, a second passivation layer 950 may be formed in the narrow trench 605, for example including on the conductive material 930 of the wide trench 600. The second passivation layer 950 may be a conformal passivation layer. Referring to FIG. 9E, the narrow trench 605, including within the wide trench 600, may be filled with a filler material 960. In some embodiments, the filler material 960 may include a conductive material, for example polysilicon. The filler material 960 may also be deposited on the FS 258, which may then be patterned, etched, and coupled with appropriate circuitry of the SPAD imager 100 as described above.

The conductive material 930 may be in electrical contact with the substrate 254 in the transition region between the narrow trench 605 and wide trench 600, for example between the two passivation layers 620, 950. The conductive material 930 may form the first contact for one or more adjacent SPADs 104-1, 104-2. For example, the first contact may be at the stepped region on one or both sides of the isolation trench 252.

### Third Subset of Exemplary Embodiments

Next, a third subset of embodiments of forming an improved trench isolation structure 252 will be described. The third subset of embodiments includes a trench structure 252 having a buried first contact located substantially at the corner of one or more SPAD pixels 260, and no or substantially no first contact located along any side of the one or more SPAD pixels 260. The third subset of embodiments may include the buried first contact located substantially at the point where four SPAD pixels 260 meet, and the buried first contact may be electrically coupled with, for example, one, two, three, or four of the adjacent SPAD pixels 260. Disposing the first contact substantially in the corner intersections of SPAD pixels 260 may allow for a smaller critical dimension of the trench structure 252 and closer spacing of the SPAD pixels 260.

Embodiments of the third subset of embodiments of trench structures 252 limit the first contact for each SPAD 104-1 to one or more corner regions of the respective SPAD pixel 260, further increasing the distance between the first and second contacts of the SPAD 104-1 compared to having the first contact located along a side of the SPAD pixel 260. The increased distance further decreases the electric field and decreases the risk of edge breakdown of the SPAD 104-1.

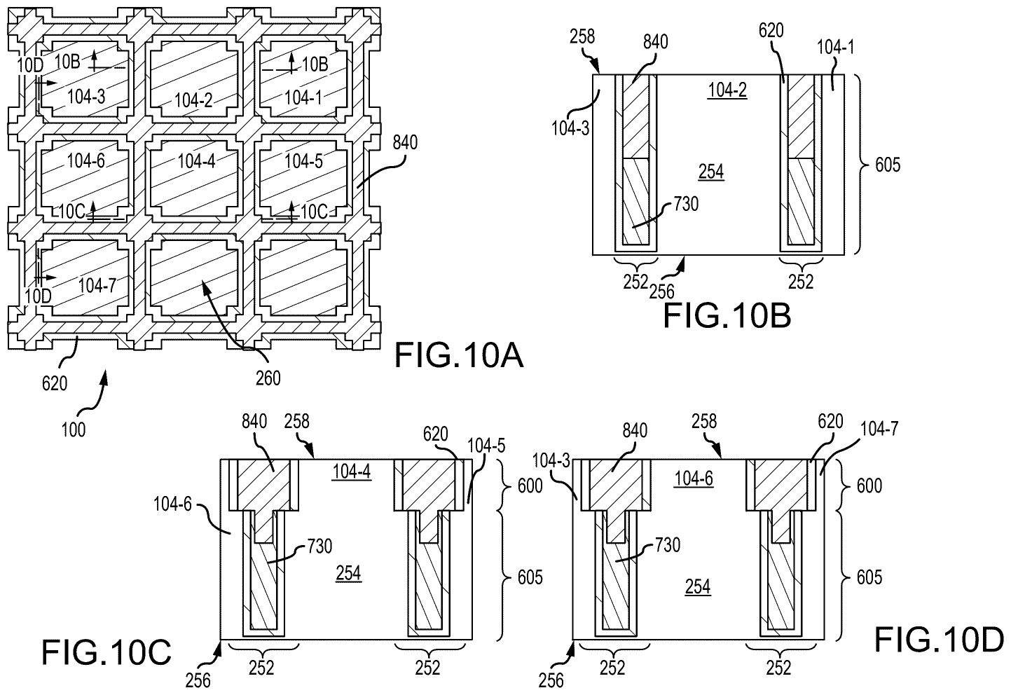

The other subsets of embodiments described above and below include variations that are also included within this third subset of embodiments. For example, referring to FIGS. 10A-E, the sixth exemplary embodiments described above may include a variation having the trench structures 252 described with respect to FIGS. 8A-E located substantially at the corners of the respective SPAD pixels 260.

FIG. 10A representatively illustrates the relative horizontal arrangement of the various components of the trench structure 252 without consideration of the vertical locations of such structures. FIGS. 10B-D illustrate the relative vertical arrangement of the various components of the trench structure.

Referring to FIG. 10A, the array of SPADs 104-1, 104-2, 104-3, 104-4, 104-5, 104-6, 104-7 may include the narrow trench 605 lined with the passivation layer 620 substantially surrounding the SPAD pixels 260, having no opening in the passivation layer and therefore preventing formation of the first contact on the sides of the respective SPAD pixels 260. The array of SPADs 104-1, 104-2, 104-3, 104-4, 104-5, 104-6, 104-7 may include the trench structure 252 as described and illustrated with respect to FIG. 8E located at the furthest extent(s) of one or more sides of the respective SPAD pixels 260. That is, the trench structure 252 described with respect to FIG. 8E may be located at one or more corners of each SPAD pixel 260 to provide the first contact for one or more adjacent SPADs.

FIGS. 10C-D are second and third cross-sections as referenced in FIG. 10A, which illustrate how a trench isolation structure 252 described and illustrated in FIG. 8E above may be formed at the corners of one or more SPAD pixels 260 in these sixth embodiments. The trench structure 252 may include the wide trench 600 and narrow trench 605, and may be filled with the first conductive material 730 and the second conductive material 840. In some embodiments, the first conductive material 730 may include polysilicon, and the second conductive material may include tungsten.

The trench structure 252 may include the opening at the passivation layer 620 at the transition region to allow the second conductive material 840 to electrically couple with the substrate 254 to form the first contact with the respective SPADs 104-3, 104-4, 104-5, 104-6, 104-7 at one or more corners of the respective SPAD pixels 260. In some embodiments, the trench structure 252 at the corners of the SPAD pixels 260 may be symmetrical in two orthogonal directions planar to the FS 258 and BS 256, for example as shown by the cross sections of FIG. 10C and FIG. 10D.

Referring to FIG. 10B, which is a first cross-section as referenced in FIG. 10A, the wide trench 600 and transition region having the passivation layer opening may not be formed along the remainder of the sides of the SPAD pixels 260. In some embodiments, only the narrow trench 605 portion of the trench structure 252 may be formed along the remainder of the sides of the SPAD pixels 260. The narrow trench 605 structures along the sides of the SPAD pixels 260 may be formed at the same time as the narrow trench 605 structures at the corners of the SPAD pixels 260, and may be suitably filled with the first conductive material 730 and the second conductive material 840.

The narrow trench 605 structures along the sides of the SPAD pixels 260 may therefore have the same or similar arrangement of structures and materials as the narrow trench 605 structures formed in the corners of the SPAD pixels 260. The second conductive material 840 is prevented from electrically coupling with the substrate 254 by the unbroken passivation layer 620 of the narrow trench.

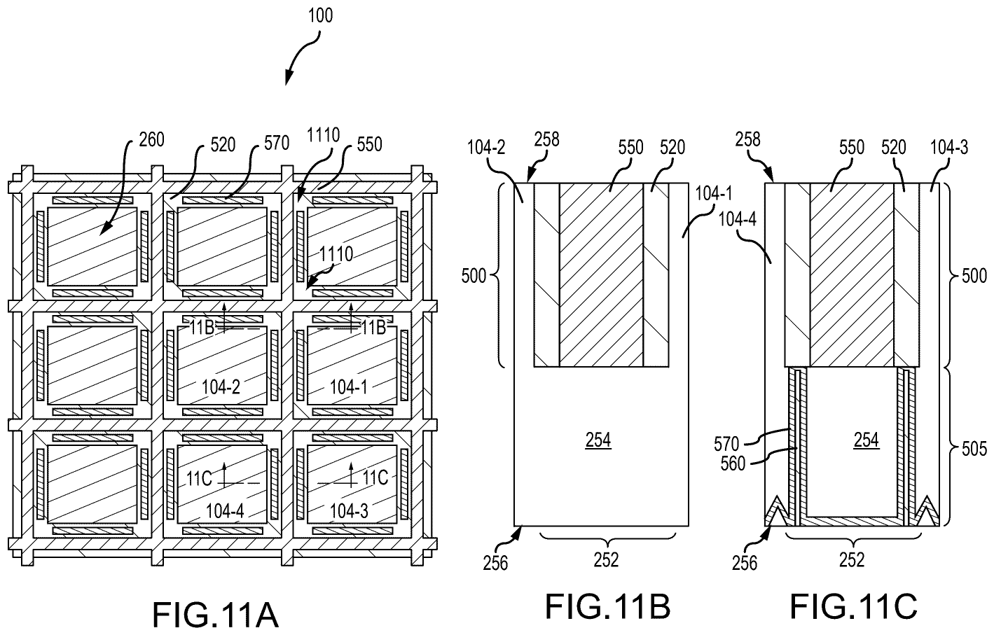

For further example, referring to FIGS. 11A-C, the third exemplary embodiments described above with respect to FIGS. 5A-C may include variations having the FS trench 500 described with respect to FIG. 5B located substantially at the corners of the respective SPAD pixels 260 and the trench structures 252 described with respect to FIG. 5C located along the remainder of the sides of the respective SPAD pixels 260. The variations may include a segmented BS trench 505. FIG. 11A representatively illustrates the relative horizontal arrangement of the various components of the trench structure 252 without consideration of the vertical locations of such structures. FIGS. 11B and 11C illustrate the relative vertical arrangement of the various components of the trench structure.

Referring to FIG. 11A, the array of SPADs 104-1, 104-2, 104-3, 104-4 may include the isolation trench structure 252 as described and illustrated with respect to FIG. 11C substantially surrounding the SPAD pixels 260. Similar to FIG. 5C, the isolation trench structure 252 here in FIG. 11C includes both the FS trench 500 and BS trench 505 structures. These FS trench 500 and BS trench 505 structures may have no opening between the facing portions of the BS trench 505 and FS trench 500, therefore preventing formation of the first contact on the sides of the respective SPAD pixels 260.

The array of SPADs 104-1, 104-2, 104-3, 104-4 may include the FS trench 500 as described and illustrated with respect to FIG. 11B, without the BS trench 505, located at the furthest extent(s) 1110 of one or more sides of the respective SPAD pixels 260. That is, the FS trench 500 described with respect to FIG. 11B may be located adjacent to one or more corners of each SPAD pixel 260 to provide the first contact for one or more adjacent SPADs 104-1, 104-2, 104-3, 104-4.

Referring to FIG. 11B, which is a first cross-section as referenced in FIG. 11A, a trench isolation structure 252 according to the FS trench 500 described with respect to the third exemplary embodiments above may be formed at the corners of one or more SPAD pixels 260. Similar to FIG. 5B, the FS trench 500 in FIG. 11B may include the opening at the bottom of the FS trench 500 to allow the conductive material 550 to electrically couple with the substrate 254 to form the first contact at the corners of one or more respective SPAD pixels 260.

In some embodiments, the trench structure 252 at the corners of the SPAD pixels 260 may be symmetrical in two orthogonal directions planar to the FS 258 and BS 256. In some such embodiments, no BS trench 505 exists at the corner intersections of SPAD pixels 260, which may have a negligible or small negative impact on SPAD pixel isolation.

Referring to FIG. 11C, which is a second cross-section as referenced in FIG. 11A, a trench isolation structure 252 along the remainder of the sides of the SPAD pixels 260 may include both the FS trench 500 and BS trench 505 described with respect to the third exemplary embodiments above, having the hi-k material 570 and/or passivation layer 560 of the BS trench in contact with the passivation layer 520 of the FS trench 500, preventing electrical coupling of the conductive material 550 with the neighboring SPADs 104-3, 104-4. In some embodiments, the FS trench 500 at the corners of the SPAD pixels 260 may be formed at the same time as the FS trench 500 along the sides of the SPAD pixels 260.

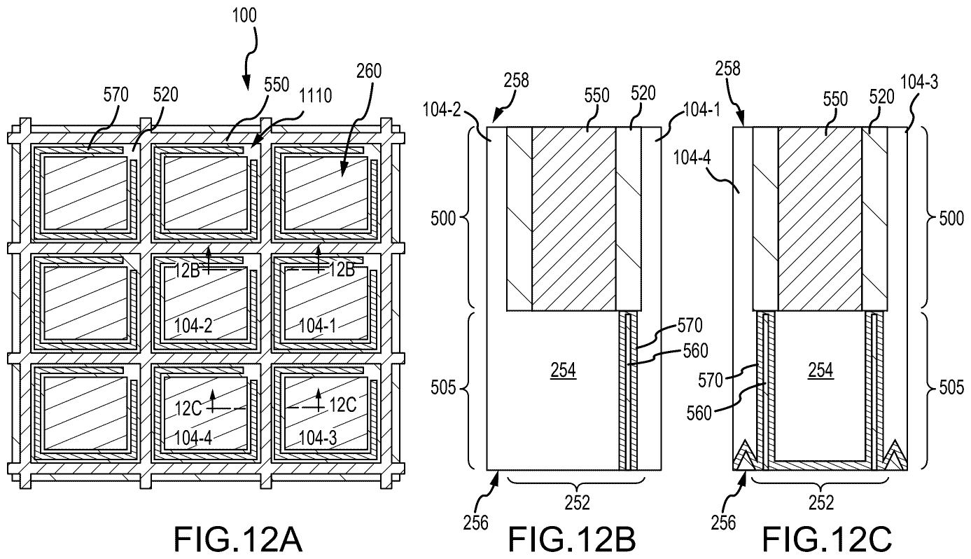

For further example, referring to FIGS. 12A-C, the third exemplary embodiments described above with respect to FIGS. 5A-C may include a variation having the trench structures 252 described with respect to FIG. 5B located substantially at the corners of the respective SPAD pixels 260, and the trench structures 252 described with respect to FIG. 5C located along the remainder of the sides of the respective SPAD pixels 260. The variations may include a segmented BS trench 505.

FIG. 12A representatively illustrates the relative horizontal arrangement of the various components of the trench structure 252 without consideration of the vertical locations of such structures. FIGS. 12B and 12C illustrate the relative vertical arrangement of the various components of the trench structure.

As shown in FIG. 12A, the array of SPADs 104-1, 104-2, 104-3, 104-4 may include the isolation trench structure 252 as described and illustrated with respect to FIG. 12C substantially surrounding the SPAD pixels 260. Similar to FIG. 5C, the isolation trench structure 252 in FIG. 12C here includes both the FS trench 500 and BS trench 505 structures. These FS trench 500 and BS trench 505 structures may have no opening between the facing portions of the BS trench 505 and FS trench 500, therefore preventing formation of the first contact on the sides of the respective SPAD pixels 260.

Also in FIG. 12A, the array of SPADs 104-1, 104-2, 104-3, 104-4 may include the isolation trench structure 252 as described and illustrated with respect to FIG. 12B located at the furthest extent(s) 1110 of one or more sides of the respective SPAD pixels 260. Similar to FIG. 5B, the isolation trench structure 252 of FIG. 12B here includes the FS trench 500, and the BS trench 505 on one side of the isolation trench structure 252.

In some embodiments, the trench structure 252 at the corners of the SPAD pixels 260 may be open to only one adjacent SPAD pixel 260. That is, the arrangement of the FS trench 500 and BS trench 505 described with respect to FIG. 12B may be located at one corner of each SPAD pixel 260 to provide the first contact to only one adjacent SPAD 104-1. In some such embodiments, SPAD pixel isolation may be retained as the substrate 254 of each SPAD pixel remains laterally isolated from neighboring SPAD pixels.

In some embodiments, the FS trench 500 at the corners of the SPAD pixels 260 may be formed at the same time as the FS trench 500 along the sides of the SPAD pixels 260, and the BS trench 505 at the corners of the SPAD pixels 260 may be formed at the same time as the BS trench 505 along the sides of the SPAD pixels 260.

### Fourth Subset of Exemplary Embodiments

Next, a fourth subset of embodiments of forming an improved trench isolation structure 252 will be described. The fourth subset of embodiments includes a trench structure 252 having the first contact located within the trench structure 252 substantially at the same surface of the substrate as the second contact of the SPAD 104-1. In some embodiments, the SPAD 104-1 has the second contact, for example the cathode, at or near the frontside of the substrate and the first contact, for example the anode, at or near the frontside. The fourth subset of embodiments may include the first contact electrically coupled with one, two, three, or four of the adjacent SPAD pixels 260.

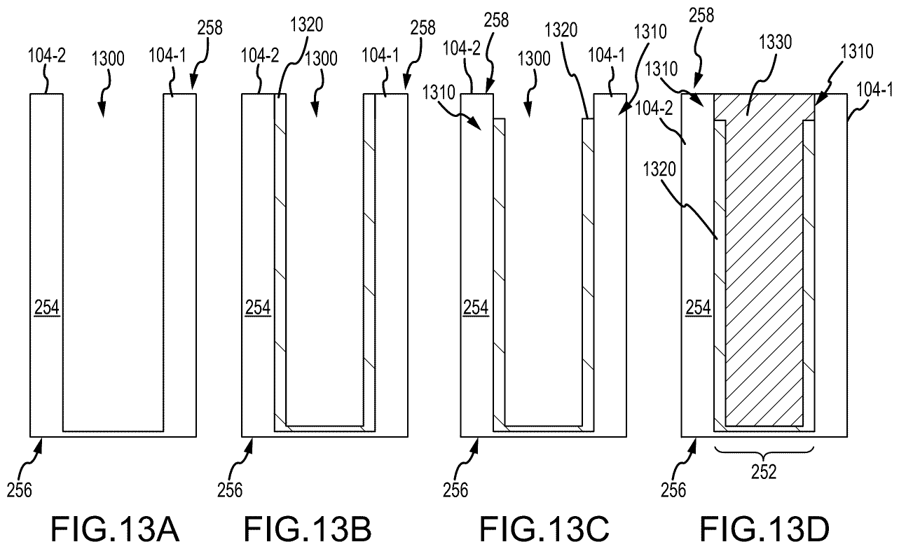

Referring to FIGS. 13A-D, the fourth subset of trench isolation embodiments may include some eighth exemplary embodiments having a trench structure 252 that may partially or fully extend along one or more edges of one or more SPAD pixels 260. The trench structure 252 may include an FS trench lined with a passivation layer, wherein an opening in the passivation layer near the FS 258 allows a conductive material filler to electrically couple with the substrate 254 proximate to the FS 258.

Referring to FIG. 13A, as described above, an FS trench 1300 may be formed in the substrate 254 to any suitable depth. Referring to FIG. 13B, a passivation layer 1320 may be formed in the FS trench 1300. The passivation layer 1320 may be a deposited conformal passivation layer.

Referring to FIG. 13C, some passivation layer 1320 may be removed from the top of the FS trench 1300. For example, a spacer etch may be performed to completely remove the passivation layer 1320 from a top portion of the FS trench 1300 proximate to the FS 258. In some embodiments, the passivation layer 1320 at the bottom of the FS trench 1300 may also be partially or completely removed, for example from the same spacer etch.

The portion 1310 of the substrate 254 proximate to the opening of the passivation layer 1320 at the top of the FS trench 1300 may be doped, for example implanted with charged ions as described above. In some embodiments, the same photoresist used for the spacer etch may be used for the ion implantation prior to stripping the photoresist. In other embodiments, the substrate 254 and/or FS trench 1300 may be separately patterned for the ion implantation. The one or more photoresists may be suitably stripped, and the ion implant may then be activated as described above.

Referring to FIG. 13D, a conductive material 1330 may be deposited in the FS trench 1300. The conductive material 1330 may be in electrical contact with the substrate 254 proximate to the FS 258, and in some embodiments also through the bottom of the FS trench 1300. The conductive material 1330 may for example include tungsten.

In some embodiments, the conductive material 1330 may also be deposited on the FS 258 of the substrate 254 (not shown), which may then be patterned and etched as part of the wiring layer 206 (not shown). The conductive material 1330 may be coupled through one or more conductive signal lines 212, 214 to appropriate circuitry of the SPAD imager 100 to form the first contact for one or more adjacent SPADs 104-1, 104-2, for example proximate to the FS 258 on one or both sides of the isolation trench 252.

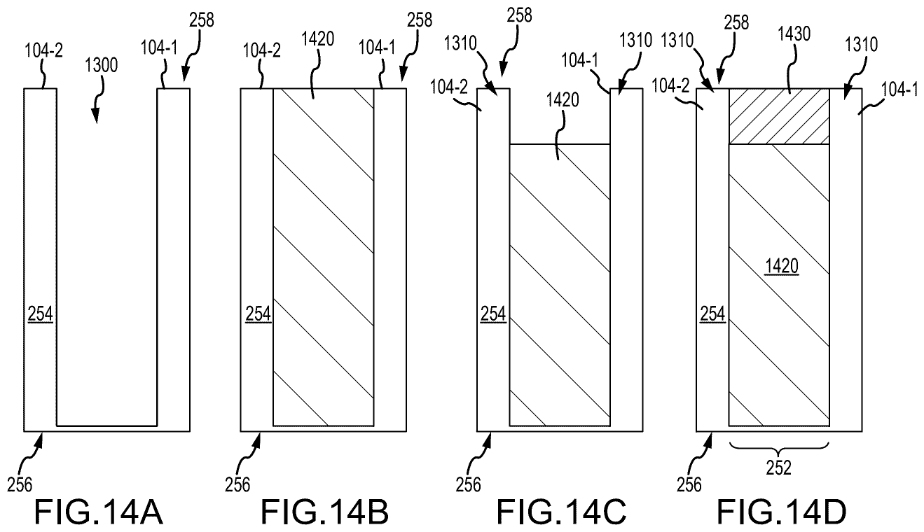

Referring to FIGS. 14A-D, the fourth subset of trench isolation embodiments may include some ninth exemplary embodiments having a trench structure 252 that may partially or fully extend along one or more edges of one or more SPAD pixels 260. The trench structure 252 may include an FS trench filled with a passivation layer except proximate to the FS 258, wherein a conductive material filler in the FS trench proximate to the FS 258 electrically couples with the substrate 254.

Referring to FIG. 14A, as described above, an FS trench 1300 may be formed in the substrate 254 to any suitable depth. Referring to FIG. 14B, the FS trench 1300 may be filled with a passivation material 1420, for example an oxide such as silicon dioxide. In some embodiments, the FS trench 1300 may be completely filled with the passivation material 1420. In some embodiments, a top portion of the FS trench 1300 may be left without the passivation material 1420.

Referring to FIG. 14C, some of the passivation material 1420 may be removed from the top of the FS trench 1300. For example, a spacer etch may be performed to completely remove the passivation material 1420 from a top portion of the FS trench 1300 proximate to the FS 258. The passivation material 1420 may be removed to any suitable depth within the FS trench 1300.

The portion 1310 of the substrate 254 proximate to the removed or otherwise absent passivation material 1420 at the top of the FS trench 1300 may be doped, for example implanted with charged ions as described above. In some embodiments, the same photoresist used for the spacer etch may be used for the ion implantation prior to stripping the photoresist. In other embodiments, the substrate 254 and/or FS trench 1300 may be separately patterned for the ion implantation. The one or more photoresists may be suitably stripped, and the ion implant may then be activated as described above.

Referring to FIG. 14D, a conductive material 1430 may be deposited in the FS trench 1300. The conductive material 1430 may be in electrical contact with the substrate 254 proximate to the FS 258. The conductive material 1430 may for example include tungsten.

In some embodiments, the conductive material 1430 may also be deposited on the FS 258 of the substrate 254 (not shown), which may then be patterned and etched as part of the wiring layer 206 (not shown). The conductive material 1430 may be coupled through one or more conductive signal lines 212, 214 to appropriate circuitry of the SPAD imager 100 to form the first contact for one or more adjacent SPADs 104-1, 104-2, for example proximate to the FS 258 on one or both sides of the isolation trench 252.

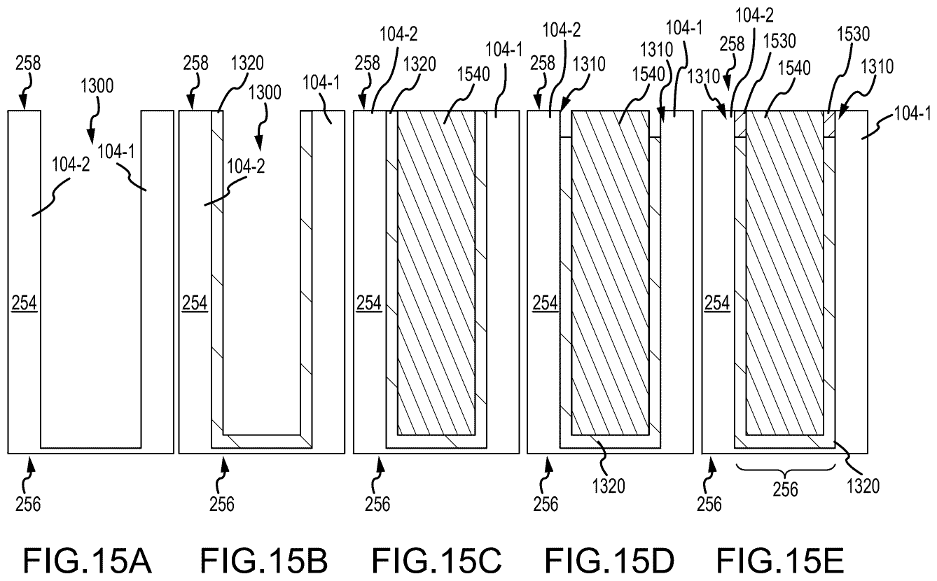

Referring to FIGS. 15A-E, the fourth subset of trench isolation embodiments may include some tenth exemplary embodiments having a trench structure 252 that may partially or fully extend along one or more edges of one or more SPAD pixels 260. The trench structure 252 may include an FS trench lined with a passivation layer and filled with a first conductive material, wherein an opening in the passivation layer near the FS 258 allows a second conductive material to electrically couple with the substrate 254 proximate to the FS 258.

Referring to FIG. 15A, as described above, an FS trench 1300 may be formed in the substrate 254 to any suitable depth. Referring to FIG. 15B, a passivation layer 1320 may be formed in the FS trench 1300. The passivation layer 1320 may be a deposited conformal passivation layer. Referring to FIG. 15C, the FS trench 1300 may be filled with a first conductive material 1540. In some embodiments, the first conductive material 1540 may include polysilicon.

Referring to FIG. 15D, in some embodiments, some passivation layer 1320 may be removed from the top of the FS trench 1300. For example, a spacer etch may be performed to completely remove the passivation layer 1320 from a top portion of the FS trench 1300 proximate to the FS 258. In some embodiments, the first conductive material 1540 remains substantially the same before and after removal of the passivation layer 1320.

The portion 1310 of the substrate 254 proximate to the opening of the passivation layer 1320 at the top of the FS trench 1300 may be doped, for example implanted with charged ions as described above. In some embodiments, the same photoresist used for the spacer etch may be used for the ion implantation prior to stripping the photoresist. In other embodiments, the substrate 254 and/or FS trench 1300 may be separately patterned for the ion implantation. The one or more photoresists may be suitably stripped, and the ion implant may then be activated as described above.

Referring to FIG. 15E, a second conductive material 1530 may be deposited in the FS trench 1300, for example in the cavity provided by the removal of the passivation layer 1320. The second conductive material 1530 may be in electrical contact with the substrate 254 proximate to the FS 258. The second conductive material 1530 may for example include tungsten.

In some embodiments, the first conductive material 1540 and/or the second conductive material 1530 may also be deposited on the FS 258 of the substrate 254 (not shown), which may then be patterned and etched as part of the wiring layer 206 (not shown). The conductive first conductive material 1540 and/or the second conductive material 1530 may be coupled through one or more conductive signal lines 212, 214 to appropriate circuitry of the SPAD imager 100 to form the first contact for one or more adjacent SPADs 104-1, 104-2, for example proximate to the FS 258 on one or both sides of the isolation trench 252.

### Fifth Subset of Exemplary Embodiments

Next, a fifth subset of embodiments of forming an improved trench isolation structure 252 will be described. The fifth subset of embodiments include an FS trench having a passivation layer and a conductive material filler arranged to form a first contact of one or more SPADs 104-1, as described according to numerous exemplary embodiments above. The fifth subset of embodiments further includes a segmented BS trench having a first portion that contacts a single side of the bottom of the FS trench, and a second portion that contacts both sides of the bottom of the FS trench.

The segmented BS trench may be applied to embodiments of the first through fourth subsets of exemplary embodiments described above. For example, embodiments of the fifth subset of exemplary embodiments may include trench structures 252 according to the third exemplary embodiments and as described with respect to FIGS. 5, 11A-C, and 12A-C. Segmented BS trench structures, for example as described with respect to FIGS. 5, 11A-C, and 12A-C, may also be used in conjunction with the FS trench structures described above. Embodiments of the fifth subset of exemplary embodiments therefore also include variations of the first, second, fourth, fifth, sixth, seventh, eighth, ninth, and tenth exemplary embodiments described above.

Therefore, according to the various embodiments of the several subsets of exemplary embodiments described above, an isolation trench 252 may include a trench having a single passivation layer and a metal within the trench and contacting the substrate 254 through an opening in the passivation layer. An isolation trench 252 may include a single passivation layer in an annular ring around each SPAD pixel 260 and a metal between the annular rings and contacting the substrate 254 away from the FS 258.

An isolation trench 252 may include a stepped region. For example, an isolation trench 252 may include an FS trench having a single passivation layer and filled with polysilicon toward the BS portion of the FS trench and also filled with a metal toward the FS of the FS trench, where the metal contacts the substrate 254 through an opening in the passivation layer at the stepped region. An isolation trench 252 may include an FS trench having a single passivation layer and filled with polysilicon and also filled with a metal toward the FS of the FS trench, where the polysilicon contacts the substrate 254 through an opening in the passivation layer at the stepped region.

An isolation trench 252 may include an FS trench having a single passivation layer with metal filling inside the trench, where the metal contacts the substrate 254 away from the FS 258, and may include a BS trench formed as a deep trench from the BS 256 using a hi-k material and silicon dioxide. The FS trench and the BS trench may be separated and/or connected. In some such embodiments, the FS trench and BS trench are connected in segments to allow a path for the electric field for the anode/cathode and to have overlaps to prevent light leakage (e.g., crosstalk) due to scattering from scattering structures in or near the pixels 260.

An isolation trench 252 may include an FS trench having two passivation layers, where an inner passivation layer is filled with polysilicon and a metal is located between an outer and the inner passivation layers and contacts the substrate 254. The metal may be formed in a ring around the polysilicon. An isolation trench 252 may include a FS trench line or filled with a passivation layer and including a metal near the FS 258, where the metal contacts the substrate 254.

An isolation trench 252 may include embodiments having the first contact of the SPAD 104-1 only at the intersections of three or more pixels, for example at the corners. The contact at the intersections may include an opening in a single passivation layer allowing a metal of the trench 252 to contact the substrate, and no opening in the single passivation layer along the remainder of the sides of the pixels 260

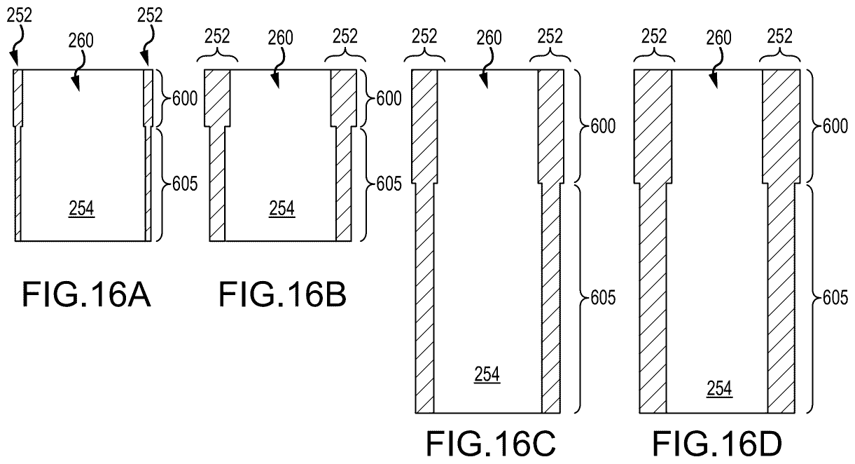

FIGS. 16A-D illustrate exemplary geometrical arrangements of representative isolation trench structures. For example, stepped trench structures 252 according to any of the first through fourth stepped isolation trench structures may include a narrow trench 605 that is approximately twice as deep as the wide trench 600 of the stepped trench structure 252. The SPAD pixel 260 may have any suitable pitch as described above, for example about 2 μm to about 3 μm.

Referring to FIG. 16A, the substrate 254 may have a depth D1 of about 3 μm, the wide trench 600 may have a depth of about 1 μm, and the narrow trench 605 may have a depth of about 2 μm. The wide trench 600 may have a critical dimension (CD) of about 150 nm and the narrow trench 605 may have a critical dimension of about 100 nm. Therefore, the wide trench 600 may have an aspect ratio (AR) of about 6.7 and the narrow trench 605 may have an aspect ratio of about 20.

Referring to FIG. 16B, the substrate 254 may have a depth D1 of about 3 μm, the wide trench 600 may have a depth of about 1 μm, and the narrow trench 605 may have a depth of about 2 μm. The wide trench 600 may have a critical dimension (CD) of about 400 nm and the narrow trench 605 may have a critical dimension of about 200 nm. Therefore, the wide trench 600 may have an AR of about 2.5 and the narrow trench 605 may have an AR of about 10.

Referring to FIG. 16C, the substrate 254 may have a depth D1 of about 6 μm, the wide trench 600 may have a depth of about 2 μm, and the narrow trench 605 may have a depth of about 4 μm. The wide trench 600 may have a critical dimension (CD) of about 400 nm and the narrow trench 605 may have a critical dimension of about 200 nm. Therefore, the wide trench 600 may have an AR of about 5 and the narrow trench 605 may have an AR of about 20.

Referring to FIG. 16D, the substrate 254 may have a depth D1 of about 6 μm, the wide trench 600 may have a depth of about 2 μm, and the narrow trench 605 may have a depth of about 4 μm. The wide trench 600 may have a critical dimension (CD) of about 600 nm and the narrow trench 605 may have a critical dimension of about 400 nm. Therefore, the wide trench 600 may have an AR of about 3.3 and the narrow trench 605 may have an AR of about 10.

Other embodiments may similarly use one or more of the narrow or wide trench geometries even without a stepped trench arrangement. For example, some embodiments according to the eighth, ninth, and/or tenth exemplary embodiments may have a critical dimension as described with respect to the wide trench 600 or narrow trench 605. For further example, some embodiments according to the first exemplary embodiments may have the annular trenches 310 formed at the critical dimension of the wide trench 600 and the central trench 340 at the critical dimension of the narrow trench 605.

Various embodiments therefore provide SPAD-based systems, devices, and methods having a buried contact. Various embodiments may include one of the anode or cathode of a SPAD within isolation trench structures. The buried contact may be located within the isolation trench near the same side of the substrate as the other of the anode or cathode, and/or may be located at some distance from the side of the substrate having the other of the anode or cathode.

Systems, devices, and methods as described herein provide for increased spacing between the anode and cathode of respective SPADs and reduced probability of edge breakdown of the avalanche region of the respective SPADs. Various embodiments allow for smaller pixels, smaller critical dimensions of the pixels and/or trench structures, or the like. Various embodiments therefore provide for increased imager resolution.

It will be recognized that the embodiments described above with respect to SPAD-based pixels may be applied to other imaging pixels, for example to CMOS image sensors or the like. It will be recognized that embodiments according to the present description may be applied to backside imaging devices and/or frontside imaging devices. The various imager device structures, isolation trench structures, buried contacts, materials, processing steps, and the like shown and described above may be arranged in any number of equivalent embodiments.

The general concepts set forth herein may be adapted to any number of alternate but equivalent embodiments. The term “exemplary” is used herein to represent one example, instance or illustration that may have any number of alternates. Any implementation described herein as “exemplary” is not necessarily to be construed as preferred or advantageous over other implementations, nor is it necessarily intended as a model that must be duplicated in other implementations. While several exemplary embodiments have been presented in the foregoing detailed description, it should be appreciated that a vast number of alternate but equivalent variations exist, and the examples presented herein are not intended to limit the scope, applicability, or configuration of the invention in any way. To the contrary, various changes may be made in the function and arrangement of elements described without departing from the scope of the claims and their legal equivalents.

What is claimed is:

1. A semiconductor device, comprising:
a substrate having a frontside and a backside;
a first single-photon avalanche diode (SPAD) in the substrate and having a first contact proximate to the frontside of the substrate;
a second SPAD in the substrate and located next to the first SPAD; and
a trench isolation structure in the substrate interposed between the first and second SPAD, comprising:
a frontside trench having one or more vertical walls and a horizontal surface;
a continuous passivation layer lining the frontside trench, wherein the passivation layer includes an opening at the horizontal surface of the frontside trench; and
a conductive material disposed within the frontside trench and laterally separated from the substrate by the passivation layer, wherein the conductive material is electrically coupled with the substrate through the opening of the passivation layer to form a second contact.

2. The semiconductor device of claim 1, wherein the conductive material comprises tungsten.

3. The semiconductor device of claim 1, wherein the substrate proximate to the opening of the passivation layer is positively doped.

4. The semiconductor device of claim 1, wherein the frontside trench comprises:
a wide trench located proximate to the frontside;
a narrow trench extending from a bottom surface of the wide trench toward the backside; and
a transition region between the wide trench and the narrow trench, the transition region including the opening in the passivation layer.

5. The semiconductor device of claim 4, wherein the continuous passivation layer includes a second opening at a bottom surface of the narrow trench.

6. The semiconductor device of claim 1, wherein:
the opening of the passivation layer comprises:
a first opening adjacent to a first corner of the first SPAD; and
a second opening adjacent to a second corner of the first SPAD; and
the passivation layer includes no opening between the first and second corners.

7. The semiconductor device of claim 1, wherein:
the frontside trench has a first side adjacent the first SPAD, a second side adjacent the second SPAD, and a bottom surface; and
the trench isolation structure further comprises:
a segmented backside trench structure comprising:
a first portion comprising a dielectric material in contact with the bottom surface of the frontside trench on the first side of the frontside trench; and
a second portion comprising the dielectric material in contact with the bottom surface of the frontside trench on both the first side of the frontside trench and a second side of the frontside trench.

8. The semiconductor device of claim 7, wherein the segmented backside trench structure comprises an overlap of two first portions of the backside trench structure.

9. The semiconductor device of claim 1, wherein the second contact is at a first depth from the frontside, wherein the first depth is equal to at least half of a distance between the frontside and the backside.

10. A semiconductor device, comprising:
a substrate having a first surface and a second surface;
a first single-photon avalanche diode (SPAD) in the substrate and having a first contact proximate to the first surface of the substrate;
a second SPAD in the substrate; and
a trench isolation structure in the substrate interposed between the first and second SPAD, comprising:
a trench comprising:
a wide trench located proximate to the first surface of the substrate;
a narrow trench extending through a bottom surface of the wide trench toward the second surface of the substrate; and
a transition region between the wide trench and the narrow trench;
a continuous passivation layer lining the wide trench and the narrow trench,
wherein the passivation layer includes an opening at the transition region; and
a conductive material disposed within the trench and electrically coupled with the substrate through the opening of the passivation layer to form a second contact.

11. The semiconductor device of claim 10, wherein the substrate proximate to the opening of the passivation layer is positively doped.

12. The semiconductor device of claim 10, wherein the continuous passivation layer includes a second opening at a bottom surface of the narrow trench.

13. The semiconductor device of claim 10, wherein the conductive material comprises tungsten.

14. The semiconductor device of claim 10, wherein the conductive material comprises:
a first portion comprising polysilicon; and
a second portion comprising tungsten deposited over the first portion.

15. The semiconductor device of claim 10, wherein:
the opening of the passivation layer comprises:
a first opening adjacent to a first corner of the first SPAD; and
a second opening adjacent to a second corner of the first SPAD; and
the passivation layer includes no opening between the first and second corners.

16. A method of forming a trench isolation structure between a first single-photon avalanche diode (SPAD) and a second SPAD in a substrate, wherein the substrate has a frontside and a backside and the first SPAD has a first electrical contact proximate to the frontside of the substrate, the method comprising:
etching a frontside trench between the first SPAD and the second SPAD;
forming a continuous passivation layer in the frontside trench;
forming an opening in the continuous passivation layer at a horizontal surface of the frontside trench; and
forming a conductive material in the frontside trench, wherein the conductive material is electrically coupled with the substrate through the opening to form a second electrical contact.

17. The method of claim 16, further comprising:
doping the substrate proximate to the opening.

18. The method of claim 16, wherein:
etching the frontside trench comprises:
etching a wide trench; and
etching a narrow trench through a bottom surface of the wide trench;
forming the continuous passivation layer comprises forming the continuous passivation layer simultaneously in the wide trench and the narrow trench; and
forming an opening in the continuous passivation layer comprises opening the continuous passivation layer at a transition region between the wide trench and the narrow trench.

19. The method of claim 16, wherein forming an opening in the continuous passivation layer comprises opening the continuous passivation layer at a first corner and a second corner of the first SPAD without opening the continuous passivation layer between the first corner and the second corner, wherein the first corner and the second corner of the first SPAD are adjacent to the second SPAD.

20. The method of claim 16, further comprising:
forming a segmented backside trench comprising:
etching a first portion of the backside trench to a first side of a bottom surface of the frontside trench, wherein the first side is adjacent to the first SPAD;
etching a second portion of the backside trench to both the first side and a second side of the bottom surface of the frontside trench, wherein the second side of the frontside trench is adjacent to the second SPAD; and
filling the first portion and the second portion of the backside trench with a dielectric material.
